(19) United States
(12) Patent Application Publication
(10) Pub. No.: US 2009/0305490 A1
(43) Pub. Date: Dec. 10, 2009

(54) METHOD FOR PRODUCING SEMICONDUCTOR DEVICE

(75) Inventor: Hiroshi SERA, Chino-shi (JP)

Correspondence Address: OLIFF & BERRIDGE, PLC, P.O. BOX 320850, ALEXANDRIA, VA, 22320-4850, US

(73) Assignee: Seiko Epson Corporation, Tokyo (JP)

(21) Appl. No.: 12/425,016

(22) Filed: Apr. 16, 2009

(30) Foreign Application Priority Data
Jun. 4, 2008 (JP) 2008-146673

(51) Int. Cl. H01L 21/265

(52) U.S. Cl. 438/527; 257/E21.334

(57) ABSTRACT

A method for producing a semiconductor device includes forming an electrically conductive pattern so as to overlap in a plan view with part of a semiconductor layer provided on a substrate, on the opposite side of the substrate side of the semiconductor layer; implanting an impurity into the semiconductor layer using the electrically conductive pattern as a mask; reducing a superimposed region that is a region where the electrically conductive pattern and the semiconductor layer overlap with each other in a plan view by removing part of the electrically conductive pattern after the implantation of the impurity; and implanting the impurity into the semiconductor layer using the electrically conductive pattern as a mask after the reduction of the superimposed region.

### BACKGROUND

1. Technical Field

The present invention relates to a method for producing a semiconductor device.

2. Related Art

As a semiconductor device, a TFT (thin film transistor) element having an LDD (lightly doped drain) structure has been known, and as a method for producing the TFT element having the LDD structure, a method that does not need a photolithography process has been known (for example, see JP-A2006-54424).

In the method disclosed in JP-A-2006-54424, since the photolithography process can be omitted, it is possible to increase efficiency in the method of the production.

However, in the method disclosed in JP-A-2006-54424, it is difficult to further increase the production efficiency.

That is, known methods have a problem that a further increase in production efficiency is difficult.

### SUMMARY

An advantage of some aspects of the invention can be achieved as in the Embodiments described below.

A first aspect of the invention is a method for producing a semiconductor device, and the method includes forming an electrically conductive pattern so as to overlap in a plan view with part of a semiconductor layer provided on a substrate, on the opposite side of the substrate side of the semiconductor layer; implanting an impurity into the semiconductor layer using the electrically conductive pattern as a mask; reducing a superimposed region that is a region where the electrically conductive pattern and the semiconductor layer overlap with each other in a plan view by removing part of the electrically conductive pattern after the implantation of the impurity; and implanting the impurity into the semiconductor layer using the electrically conductive pattern as a mask after the reduction of the superimposed region.

The method of the first aspect includes formation of an electrically conductive pattern, a former implantation of an impurity, reduction of a superimposed region, and a later implantation of the impurity. In the formation of the electrically conductive pattern, the electrically conductive pattern is formed so as to overlap in a plan view with part of a semiconductor layer provided on a substrate, on the opposite side of the substrate side of the semiconductor layer. In the former implantation of an impurity, the impurity is implanted into the semiconductor layer using the electrically conductive pattern as a mask. By doing so, a source region and a drain region can be formed in the semiconductor layer. In the reduction of a superimposed region, the electrically conductive pattern is partially removed to reduce the region where the electrically conductive pattern and the semiconductor layer overlap with each other in a plan view. In the later implantation of the impurity, the impurity is implanted into the semiconductor layer using the electrically conductive pattern as a mask. By doing so, the impurity can be implanted into a region corresponding to the superimposed region before the reduction excluding the superimposed region after the reduction. In addition, in the later implantation of the impurity, the impurity can be also implanted into the source region and the drain region into which the impurity has been implanted in the former implantation. That is, the source region and the drain region are implanted with the impurity twice.

On the other hand, in the region corresponding to the superimposed region before the reduction excluding the superimposed region after the reduction, the impurity is implanted only once. Consequently, the concentration of the impurity in the region corresponding to the superimposed region before the reduction excluding the superimposed region after the reduction is lower than that in the region into which the impurity is implanted twice. As a result, a semiconductor device having an LDD structure in which the semiconductor layer includes a region containing the impurity at a high concentration and a region containing the impurity at a low concentration can be produced.

In the method herein, the reduction of the superimposed region can be performed in a state that the electrically conductive pattern is not provided with, for example, a resist film, as long as the superimposed region can be reduced. That is, in this method, a step of providing, for example, a resist film to the electrically conductive pattern can be omitted. Accordingly, it is possible to readily increase the efficiency in the method for producing a semiconductor device.

A second aspect of the invention is the method for producing a semiconductor device according to the above, and the implantation concentrations of the impurity in the former implantation and the later implantation are different from each other.

In the second aspect of the invention, since the implantation concentrations of the impurity are different in the former and the later implantation, a concentration difference of the impurity between a high concentration region and a low concentration region can be readily controlled.

A third aspect of the invention is the method for producing a semiconductor device according to the above, and the implantation concentration of the impurity in the later implantation is lower than that in the former implantation.

In the third aspect of the invention, since the implantation concentration of the impurity in the later implantation is lower than that in the former implantation, a concentration difference of the impurity between a high concentration region and a low concentration region can be readily increased compared to the case that the implantation concentrations are equivalent to each other in the former and the later implantation.

A fourth aspect of the invention is the method for producing a semiconductor device according to the above, and the implantation concentration of the impurity in the later implantation is higher than that in the former implantation.

In the fourth aspect of the invention, since the implantation concentration of the impurity in the later implantation is higher than that in the former implantation, a concentration difference of the impurity between a high concentration region and a low concentration region can be readily decreased compared to the case that the implantation concentrations are equivalent to each other in the former and the later implantation.

A fifth aspect of the invention is the method for producing a semiconductor device according to the above, and the formation of the electrically conductive pattern includes forming an electrically conductive film in a region covering the semiconductor layer in a plan view; forming a resist pattern so as to overlap in a plan view with part of the semiconductor layer on the opposite side of the semiconductor layer side of the electrically conductive film; and etching the electrically conductive film using the resist pattern as a resist mask. In addition, the reduction of the superimposed region is performed by etching the electrically conductive pattern in a state that the resist pattern is removed to remove part of the electrically conductive pattern.

In the fifth aspect of the invention, the formation of the electrically conductive pattern includes formation of an electrically conductive film, formation of a resist pattern, and etching treatment of the electrically conductive film. In the formation of an electrically conductive film, the electrically conductive film is formed in the region covering the semiconductor layer in a plan view. In the formation of a resist pattern, the resist pattern is formed so as to overlap in a plan view with part of the semiconductor layer on the opposite side of the semiconductor layer side of the electrically conductive film. In the etching treatment of the electrically conductive film, the electrically conductive film is etched using the resist pattern as a resist mask. By the etching treatment of the electrically conductive film, an electrically conductive pattern is formed.

Then, in the reduction of the superimposed region, part of the electrically conductive pattern is removed by further etching the electrically conductive pattern in a state that the resist pattern is removed.

In this method, in the reduction of the superimposed region, a resist film or the like is not newly formed when part of the electrically conductive pattern is removed. Accordingly, it is possible to readily increase the efficiency in the method for producing a semiconductor device.

A sixth aspect of the invention is the method for producing a semiconductor device according to the above, and the method further includes removing the resist pattern between the formation of the electrically conductive pattern and the former implantation of the impurity.

The method of the sixth aspect includes removal of the resist pattern after the formation of the electrically conductive pattern and before the former implantation of the impurity.

Implantation of an impurity may make the material constituting the resist pattern harder than before the implantation.

In the method of the sixth aspect, since the resist pattern is removed before the former implantation of the impurity, the resist pattern can be removed before the hardening thereof. Accordingly, the resist pattern can be readily removed compared to the case that the resist pattern is removed after the implantation of the impurity.

An seventh aspect of the invention is the method for producing a semiconductor device according to the above, and the method further includes removing the resist pattern between the former implantation of the impurity and the reduction of the superimposed region.

The method of the seventh aspect includes removal of the resist pattern between the former implantation of the impurity and the reduction of the superimposed region. In this method, since the resist pattern is removed after the former implantation of the impurity, the electrically conductive pattern can be readily prevented from being damaged by the implantation of the impurity.

An eighth aspect of the method for producing a semiconductor device according to the above, and the etching treatment in the reduction of the superimposed region is isotropic etching.

In the eighth aspect of the invention, since the etching treatment in the reduction of the superimposed region is performed by the isotropic etching, the superimposed region can be readily reduced.

A ninth aspect of the invention is the method for producing a semiconductor device according to the above, and the etching treatment in the reduction of the superimposed region is wet etching.

In the ninth aspect of the invention, since the etching treatment in the reduction of the superimposed region is performed by the wet etching, damage to the structure on the substrate side of the electrically conductive pattern can be readily suppressed. Furthermore, in the wet etching treatment, particles and the like adhering to the substrate can be readily removed. Therefore, substrate cleanliness can be readily increased, and it is thereby possible to readily increase yield.

A tenth aspect of the invention is a method for producing a semiconductor device, and the method includes forming an electrically conductive pattern having a laminate structure including a plurality of electrically conductive layers such that the electrically conductive pattern overlaps in a plan view with part of a semiconductor layer provided on a substrate, on the opposite side of the substrate side of the semiconductor layer; reducing a superimposed region that is a region where the electrically conductive layers and the semiconductor layer overlap with each other in a plan view by removing part of the electrically conductive pattern such that, among the plurality of electrically conductive layers, a first electrically conductive layer that is nearest the semiconductor layer remains so as to be broader than other electrically conductive layer(s) in a plan view, after the formation of the electrically conductive pattern; and implanting an impurity into the semiconductor layer using the electrically conductive pattern as a mask, after the reduction of the superimposed region.

The method of the tenth aspect includes formation of an electrically conductive pattern, reduction of a superimposed region, and implantation of an impurity. In the formation of an electrically conductive pattern, the electrically conductive pattern having a laminate structure including a plurality of electrically conductive layers is formed so as to overlap in a plan view with part of a semiconductor layer provided on a substrate, on the opposite side of the substrate side of the semiconductor layer. In the reduction of a superimposed region, part of the electrically conductive pattern is removed such that, among the plurality of electrically conductive layers, a first electrically conductive layer that is nearest the semiconductor layer is broader than other electrically conductive layer(s) in a plan view, and thereby a superimposed region that is a region where the other electrically conductive layer(s) and the semiconductor layer overlap with each other in a plan view is reduced. In the implantation of an impurity, the impurity is implanted into the semiconductor layer using the electrically conductive pattern as a mask. By doing so, the impurity is implanted into the region outside the first electrically conductive pattern in a plan view. As a result, a source region and a drain region can be formed at the outside of the first electrically conductive layer in a plan view. In addition, in the implantation of the impurity, the impurity can be implanted through the first electrically conductive layer into a region corresponding to the superimposed region before the reduction excluding the superimposed region after the reduction. Therefore, the impurity concentration in the region corresponding to the superimposed region before the reduction excluding the superimposed region after the reduction is lower than those in the source region and the drain region. Therefore, a semiconductor device having an LDD structure in which the semiconductor layer includes a region containing the impurity at a high concentration and a region containing the impurity at a low concentration can be produced.

In the method herein, the reduction of the superimposed region can be performed in a state that the electrically conductive pattern is not provided with, for example, a resist film, as long as the superimposed region can be reduced. That is, in this method, a step of providing, for example, a resist film to the electrically conductive pattern can be omitted. Accordingly, it is possible to readily increase the efficiency in the method for producing a semiconductor device.

In addition, since the electrically conductive layer overlaps in a plan view with the LDD structure region, an improvement in the characteristics due to alleviation of the electric field can be also expected.

An eleventh aspect of the invention is the method for producing a semiconductor device according to the above, and the formation of the electrically conductive pattern includes forming a laminate of a plurality of electrically conductive layers in a region covering the semiconductor layer in a plan view; forming a resist pattern so as to overlap in a plan view with part of the semiconductor layer, on the opposite side of the semiconductor layer side of the plurality of electrically conductive layers; and etching the plurality of electrically conductive layers using the resist pattern as a resist mask. In addition, in the reduction of the superimposed region, part of the electrically conductive pattern is removed by etching the plurality of electrically conductive layers in a state that the resist pattern is removed.

In the eleventh aspect of the invention, the formation of the electrically conductive pattern includes formation of a plurality of electrically conductive layers in a laminated structure, formation of a resist pattern, and etching of the plurality of electrically conductive layers. In the formation of a plurality of electrically conductive layers in a laminate structure, the plurality of electrically conductive layers is formed as a laminate at a region covering the semiconductor layer in a plan view. In the formation of a resist pattern, the resist pattern is formed so as to overlap in a plan view with part of the semiconductor layer on the opposite side of the semiconductor layer side of the plurality of electrically conductive layer. In the etching of the plurality of electrically conductive layer, the plurality of electrically conductive layers is etched using the resist pattern as a resist mask. By etching the plurality of electrically conductive layers, an electrically conductive pattern is formed.

In the reduction of the superimposed region, part of the electrically conductive pattern is removed by further etching the electrically conductive pattern in a state that the resist pattern is removed.

In this method, in the reduction of the superimposed region, part of the electrically conductive pattern is removed without newly providing a resist film or the like to the electrically conductive pattern. Therefore, it is possible to readily increase the efficiency in the method for producing a semiconductor device.

In addition, since the electrically conductive layer overlaps in a plan view with the LDD structure region, an improvement in the characteristics due to alleviation of the electric field can be also expected.

A twelfth aspect of the invention is the method for producing a semiconductor device according to the above, and the etching treatment in the reduction of the superimposed region is isotropic etching. In addition, the etching rate for the first electrically conductive layer is slower than that for the other electrically conductive layer(s).

In the twelfth aspect of the invention, since the etching treatment in the reduction of the superimposed region is performed by isotropic etching and the etching rate for the first electrically conductive layer is slower than that for the other electrically conductive layer(s), the superimposed region can be readily reduced.

A thirteen aspect of the invention is the method for producing a semiconductor device according to the above, and the etching treatment in the reduction of the superimposed region is wet etching.

In the thirteenth aspect of the invention, since the etching treatment in the reduction of the superimposed region is performed by wet etching, damage to the structure on the substrate side of the electrically conductive pattern can be readily suppressed.

Furthermore, in the wet etching, particles and the like adhering to the substrate can be readily removed. Therefore, substrate cleanliness can be readily increased, and it is thereby possible to readily increase yield.

A fourteen aspect of the invention is a method for producing a semiconductor device, the method includes forming a first resist pattern and a second resist pattern having a first region with a thickness smaller than that of the first resist pattern and a second region with a thickness larger than that of the first resist pattern at different regions on a semiconductor layer disposed on a substrate, on the opposite side of the substrate side of the semiconductor layer; implanting a first impurity into the semiconductor layer using the first resist pattern and the second resist pattern as masks; forming a first semiconductor layer so as to overlap in a plan view with the first resist pattern and a second semiconductor layer so as to overlap in a plan view with the second resist pattern by etching the semiconductor layer using the first resist pattern and the second resist pattern as resist masks; forming an electrically conductive film that covers the first semiconductor layer and the second semiconductor layer in a plan view on the opposite side of the substrate side of the first semiconductor layer and the second semiconductor layer; forming a third resist pattern so as to overlap in a plan view with part of the first semiconductor layer and a fourth resist pattern so as to overlap in a plan view with part of the second semiconductor layer on the opposite side of the substrate side of the electrically conductive film; forming a first electrically conductive pattern so as to overlap in a plan view with the third resist pattern and a second electrically conductive pattern so as to overlap in a plan view with the fourth resist pattern by etching the electrically conductive film using the third resist pattern and the fourth resist pattern as resist masks; implanting a second impurity into the first semiconductor layer and the second semiconductor layer using the first electrically conductive pattern and the second electrically conductive pattern as masks; reducing a first superimposed region that is a region where the first electrically conductive pattern and the first semiconductor layer overlap with each other in a plan view and a second superimposed region that is a region where the second electrically conductive pattern and the second semiconductor layer overlap with each other in a plan view by removing part of the first electrically conductive pattern and part of the second electrically conductive pattern, after the implantation of the second impurity; and implanting the second impurity into the first semiconductor layer and the second semiconductor layer using the first electrically conductive pattern and the second electrically conductive pattern as masks, after the reduction of the first and the second superimposed regions. In addition, the reduction of the superimposed regions is performed by etching the first electrically conductive pattern and the second electrically conductive pattern in a state that the third resist pattern and the fourth resist pattern are removed to remove part of the first electrically conductive pattern and part of the second electrically conductive pattern.

The method of the fourteenth aspect includes formation of a resist pattern, implantation of a first impurity, formation of a first semiconductor layer and a second semiconductor layer, formation of an electrically conductive film, formation of a third resist pattern and a fourth resist pattern, formation of an electrically conductive pattern, former implantation of a second impurity, reduction of superimposed regions, and later implantation of the second impurity.

In the formation of a resist pattern, a first resist pattern and a second resist pattern are formed at different regions on a semiconductor layer disposed on a substrate, on the opposite side of the substrate side of the semiconductor layer. The second resist pattern includes a first region having a thickness smaller than that of the first resist pattern and a second region having a thickness larger than that of the first resist pattern.

In the implantation of a first impurity, the first impurity is implanted into the semiconductor layer using the first resist pattern and the second resist pattern as masks. By doing so, the first impurity can be implanted through the first region into the semiconductor layer at a region where the first region of the second resist pattern overlaps in a plan view with the semiconductor layer. Here, the first resist pattern and the second region of the second resist pattern have thicknesses larger than that of the first region. Consequently, the first impurity is readily prevented from being implanted into the semiconductor layer at regions where the semiconductor layer overlaps in a plan view with the second region and the first resist pattern. In the formation of a first semiconductor layer and a second semiconductor layer, the first semiconductor layer overlapping in a plan view with the first resist pattern and the second semiconductor layer overlapping in a plan view with the second resist pattern are formed by etching the semiconductor layer using the first resist pattern and the second resist pattern as resist masks. Here, the second semiconductor layer has a region into which the first impurity has been implanted. By doing so, the second semiconductor layer can have a source region and a drain region into which the first impurity is implanted.

In the formation of an electrically conductive film, the electrically conductive film that covers the first semiconductor layer and the second semiconductor layer in a plan view is formed on the opposite side of the substrate side of the first semiconductor layer and the second semiconductor layer. In the formation of a third resist pattern and a fourth resist pattern, the third resist pattern overlapping in a plan view with part of the first semiconductor layer and the fourth resist pattern overlapping in a plan view with part of the second semiconductor layer are formed on the opposite side of the substrate side of the electrically conductive film. On this occasion, the fourth resist pattern can cover the second region by forming the fourth resist pattern in a region extending from the second region to the first region in a plan view.

In the formation of an electrically conductive pattern, a first electrically conductive pattern overlapping in a plan view with the third resist pattern and a second electrically conductive pattern overlapping in a plan view with the fourth resist pattern are formed by etching the electrically conductive film using the third resist pattern and the fourth resist pattern as resist masks. In the former implantation of a second impurity, the second impurity is implanted into the first semiconductor layer and the second semiconductor layer using the first electrically conductive pattern and the second electrically conductive pattern as masks. By doing so, the first semiconductor layer can have the regions into which the second impurity is implanted as a source region and a drain region.

In the reduction of superimposed regions, a first superimposed region that is a region where the first electrically conductive pattern and the first semiconductor layer overlap with each other in a plan view and a second superimposed region that is a region where the second electrically conductive pattern and the second semiconductor layer overlap with each other in a plan view are reduced by removing part of the first electrically conductive pattern and part of the second electrically conductive pattern. In this reduction, the first electrically conductive pattern and the second electrically conductive pattern are etched in a state that the third resist pattern and the fourth resist pattern are removed.

In the later implantation of the second impurity, the second impurity is implanted into the first semiconductor layer and the second semiconductor layer using the first electrically conductive pattern and the second electrically conductive pattern as masks. By doing so, the second impurity can be implanted into a region corresponding to the first superimposed region before the reduction excluding the first superimposed region after the reduction. In this later implantation of the second impurity, the second impurity can be also implanted into the source region and the drain region of the first semiconductor layer into which the second impurity is implanted in the former implantation. That is, the source region and the drain region of the first semiconductor layer are implanted with the second impurity twice. On the other hand, in the region corresponding to the first superimposed region before the reduction excluding the first superimposed region after the reduction, the second impurity is implanted only once. Consequently, the concentration of the second impurity in the region corresponding to the first superimposed region before the reduction excluding the first superimposed region after the reduction is lower than that in the region into which the second impurity is implanted twice.

As a result, a semiconductor device having the LDD structure in which the first semiconductor layer includes a region containing the second impurity at a high concentration and a region containing the second impurity at a low concentration and a semiconductor device including the second semiconductor layer having a region into which the first impurity is implanted can be produced. With this, a plurality of semiconductor devices different in type from each other can be produced.

In this method, when part of the first electrically conductive pattern and part of the second electrically conductive pattern are removed in the reduction of the superimposed regions, a resist film or the like is not newly provided. Therefore, it is possible to readily increase the efficiency in the method for producing a semiconductor device.

A fifteenth aspect of the invention is a method for producing a semiconductor device, and the method includes forming a first resist pattern and a second resist pattern having a first region with a thickness smaller than that of the first resist pattern and a second region with a thickness larger than that of the first resist pattern at different regions on a semiconductor layer disposed on a substrate, on the opposite side of the substrate side of the semiconductor layer; forming a first semiconductor layer so as to overlap in a plan view with the first resist pattern and a second semiconductor layer so as to overlap in a plan view with the second resist pattern by etching the semiconductor layer using the first resist pattern and the second resist pattern as resist masks; implanting a first impurity into the second semiconductor layer through the first region using the first resist pattern and the second resist pattern as masks; forming an electrically conductive film that covers the first semiconductor layer and the second semiconductor layer in a plan view on the opposite side of the substrate side of the first semiconductor layer and the second semiconductor layer; forming a third resist pattern so as to overlap in a plan view with part of the first semiconductor layer and a fourth resist pattern so as to overlap in a plan view with part of the second semiconductor layer on the opposite side of the substrate side of the electrically conductive film; forming a first electrically conductive pattern so as to overlap in a plan view with the third resist pattern and a second electrically conductive pattern so as to overlap in a plan view with the fourth resist pattern by etching the electrically conductive film using the third resist pattern and the fourth resist pattern as resist masks; implanting a second impurity into the first semiconductor layer and the second semiconductor layer using the first electrically conductive pattern and the second electrically conductive pattern as masks; reducing a first superimposed region that is a region where the first electrically conductive pattern and the first semiconductor layer overlap with each other in a plan view and a second superimposed region that is a region where the second electrically conductive pattern and the second semiconductor layer overlap with each other in a plan view by removing part of the first electrically conductive pattern and part of the second electrically conductive pattern, after the implantation of the second impurity; and implanting the second impurity into the first semiconductor layer and the second semiconductor layer using the first electrically conductive pattern and the second electrically conductive pattern as masks, after the reduction of the first and the second superimposed regions. In addition, the reduction of the superimposed regions is performed by etching the first electrically conductive pattern and the second electrically conductive pattern in a state that the third resist pattern and the fourth resist pattern are removed to remove part of the first electrically conductive pattern and part of the second electrically conductive pattern.

The method of the fifteenth aspect include formation of a resist pattern, formation of a first semiconductor layer and a second semiconductor layer, implantation of a first impurity, formation of an electrically conductive film, formation of a third resist pattern and a fourth resist pattern, formation of an electrically conductive pattern, former implantation of a second impurity, reduction of superimposed regions, and later implantation of the second impurity.

In the formation of a resist pattern, a first resist pattern and a second resist pattern are formed at different regions on a semiconductor layer disposed on a substrate, on the opposite side of the substrate side of the semiconductor layer. The second resist pattern includes a first region having a thickness smaller than that of the first resist pattern and a second region having a thickness larger than that of the first resist pattern.

In the formation of a first semiconductor layer and a second semiconductor layer, the first semiconductor layer overlapping in a plan view with the first resist pattern and the second semiconductor layer overlapping in a plan view with the second resist pattern are formed by etching the semiconductor layer using the first resist pattern and the second resist pattern as resist masks.

In the implantation of a first impurity, the first impurity is implanted into the first semiconductor layer and the second semiconductor layer using the first resist pattern and the second resist pattern as masks. By doing so, the first impurity can be implanted through the first region into the second semiconductor layer at a region where the first region of the second resist pattern overlaps in a plan view with the second semiconductor layer. With this, the second semiconductor layer can have regions into which the first impurity is implanted as a source region and a drain region. Here, the first resist pattern and the second region of the second resist pattern have thicknesses larger than that of the first region. Consequently, the first impurity is readily prevented from being implanted into the second semiconductor layer at a region where the second region overlaps in a plan view with the second semiconductor layer and the first semiconductor layer overlapping with the first resist pattern.

In the formation of an electrically conductive film, the electrically conductive film that covers the first semiconductor layer and the second semiconductor layer in a plan view is formed on the opposite side of the substrate side of the first semiconductor layer and the second semiconductor layer. In the formation of a third resist pattern and a fourth resist pattern, the third resist pattern overlapping in a plan view with part of the first semiconductor layer and the fourth resist pattern overlapping in a plan view with part of the second semiconductor layer are formed on the opposite side of the substrate side of the electrically conductive film. On this occasion, the fourth resist pattern can cover the second region by forming the fourth resist pattern in a region extending from the second region to the first region in a plan view.

In the formation of an electrically conductive pattern, a first electrically conductive pattern overlapping in a plan view with the third resist pattern and a second electrically conductive pattern overlapping in a plan view with the fourth resist pattern are formed by etching the electrically conductive film using the third resist pattern and the fourth resist pattern as resist masks. In the former implantation of a second impurity, the second impurity is implanted into the first semiconductor layer and the second semiconductor layer using the first electrically conductive pattern and the second electrically conductive pattern as masks. By doing so, the first semiconductor layer can have regions into which the second impurity is implanted as a source region and a drain region.

In the reduction of superimposed regions, a first superimposed region that is a region where the first electrically conductive pattern and the first semiconductor layer overlap with each other in a plan view and a second superimposed region that is a region where the second electrically conductive pattern and the second semiconductor layer overlap with each other in a plan view are reduced by removing part of the first electrically conductive pattern and part of the second electrically conductive pattern. In this reduction, the first electrically conductive pattern and the second electrically conductive pattern are etched in a state that the third resist pattern and the fourth resist pattern are removed.

In the later implantation of the second impurity, the second impurity is implanted into the first semiconductor layer and the second semiconductor layer using the first electrically conductive pattern and the second electrically conductive pattern as masks. By doing so, the second impurity can be implanted into a region corresponding to the first superimposed region before the reduction excluding the first superimposed region after the reduction thereof. In this later implantation of the second impurity, the second impurity can be also implanted into the source region and the drain region of the first semiconductor layer into which the second impurity is implanted in the former implantation. That is, the source region and the drain region of the first semiconductor layer are implanted with the second impurity twice. On the other hand, in the region corresponding to the first superimposed region before the reduction excluding the first superimposed region after the reduction, the second impurity is implanted only once. Consequently, the concentration of the second impurity in the region corresponding to the first superimposed region before the reduction excluding the first superimposed region after the reduction is lower than that in the region into which the second impurity is implanted twice.

As a result, a semiconductor device having an LDD structure in which the first semiconductor layer includes a region containing the second impurity at a high concentration and a region containing the second impurity at a low concentration and a semiconductor device including a second semiconductor layer having a region into which the first impurity is implanted can be produced. With this, a plurality of semiconductor devices different in type from each other can be produced.

In this method, when part of the first electrically conductive pattern and part of the second electrically conductive pattern are removed in the reduction of the superimposed regions, a resist film or the like is not newly provided. Therefore, it is possible to readily increase the efficiency in the method for producing a semiconductor device.

A sixteenth aspect of the invention is the method for producing a semiconductor device according to the above, the method further includes removing the third resist pattern and the fourth resist pattern after the formation of the electrically conductive pattern and before the former implantation of the second impurity.

The method of the sixteenth aspect includes removal of the third resist pattern and the fourth resist pattern between the formation of the electrically conductive pattern and the implantation of the second impurity.

Implantation of an impurity may make the material constituting the resist pattern harder than before the implantation.

In the method of the sixteenth aspect, since the third resist pattern and the fourth resist pattern are removed before the former implantation of the second impurity, the third resist pattern and the fourth resist pattern can be removed before hardening thereof. Accordingly, the third resist pattern and the fourth resist pattern can be readily removed compared to the case that the third resist pattern and the fourth resist pattern are removed after the implantation of the second impurity.

The seventeenth aspect of the invention is the method for producing a semiconductor device according to the above, and the method further includes removing the third resist pattern and the fourth resist pattern after the former implantation of the second impurity and before the reduction of the superimposed regions.

The method of the seventeenth aspect includes removal of the third resist pattern and the fourth resist pattern between the former implantation of the second impurity and the reduction of the superimposed regions. In this method, since the third resist pattern and the fourth resist pattern are removed after the former implantation of the second impurity, the third electrically conductive pattern and the fourth electrically conductive pattern can be readily prevented from being damaged by the implantation of the second impurity.

### BRIEF DESCRIPTION OF THE DRAWINGS

The invention will be described with reference to the accompanying drawings, wherein like numbers reference like elements.

FIG. 1 is a plan view showing a display apparatus according to a first Embodiment.

FIG. 2 is a cross-sectional view taken along the line II-II in FIG. 1.

FIG. 3 is a plan view partially showing a plurality of pixels in the first Embodiment.

FIG. 4 is a diagram showing a circuit structure of the display apparatus according to the first Embodiment.

FIG. 5 is a cross-sectional view taken along the line V-V in FIG. 3.

FIG. 6 is a plan view showing first semiconductor layers and second semiconductor layers in the first Embodiment.

FIG. 7 is a plan view showing the first semiconductor layers, the second semiconductor layers, island electrodes, scanning lines, and data lines in the first Embodiment.

FIG. 8 is a plan view showing the island electrodes, the scanning lines, and the data lines in the first Embodiment.

FIG. 9 is a plan view showing contact holes in the first Embodiment.

FIG. 10 is a plan view showing selecting transistors, driving transistors, scanning lines, data lines, a power wire, drain electrodes, and relay electrodes in the first Embodiment.

FIG. 11 is a cross-sectional view taken along the line XI-XI in FIG. 10.

FIG. 12 is an enlarged view of the area XII in FIG. 5.

FIG. 13 is a plan view showing pixel electrodes in the first Embodiment.

FIG. 14 is a timing chart of control signals supplied to each scanning line in the first Embodiment.

FIG. 15A is a diagram illustrating a step of producing an element substrate in the first Embodiment.

FIG. 15B is a diagram illustrating a step of producing the element substrate in the first Embodiment.

FIG. 15C is a diagram illustrating a step of producing the element substrate in the first Embodiment.

FIG. 15D is a diagram illustrating a step of producing the element substrate in the first Embodiment.

FIG. 16A is a diagram illustrating a step of producing the element substrate in the first Embodiment.

FIG. 16B is a diagram illustrating a step of producing the element substrate in the first Embodiment.

FIG. 16C is a diagram illustrating a step of producing the element substrate in the first Embodiment.

FIG. 16D is a diagram illustrating a step of producing the element substrate in the first Embodiment.

FIG. 17A is a diagram illustrating a step of producing the element substrate in the first Embodiment.

FIG. 173 is a diagram illustrating a step of producing the element substrate in the first Embodiment.

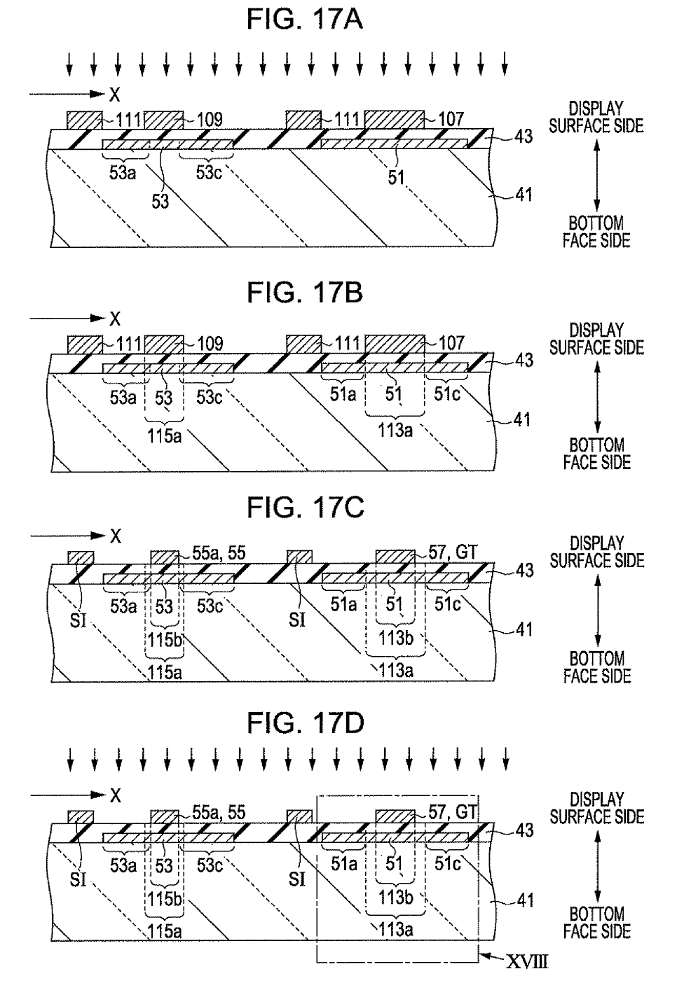

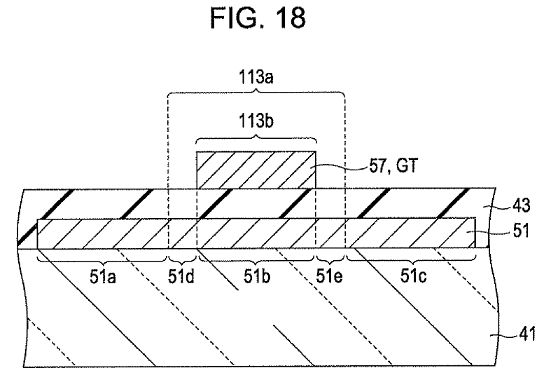

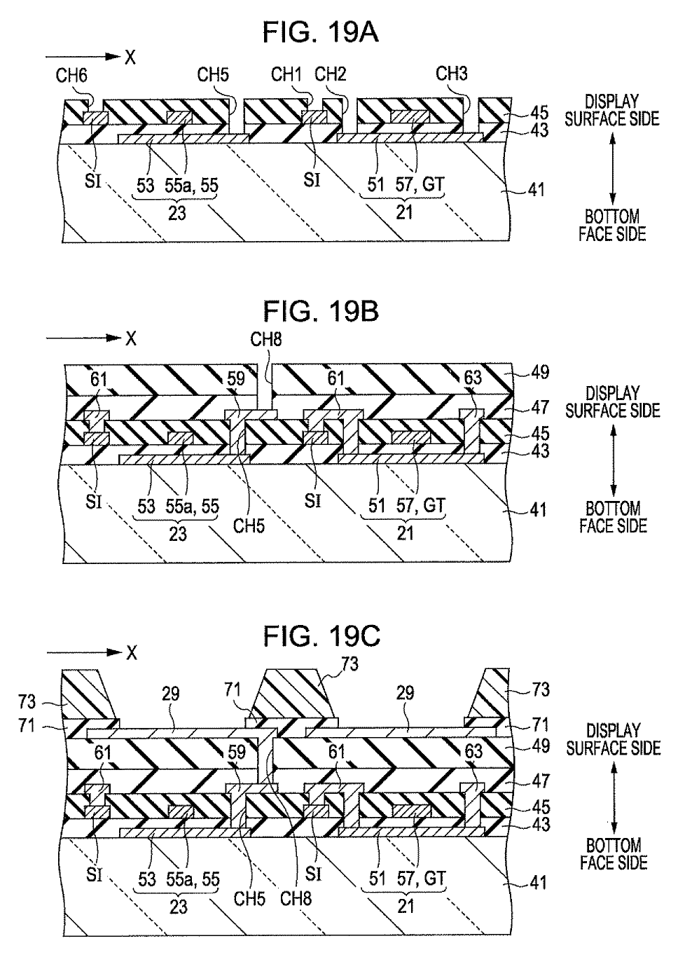

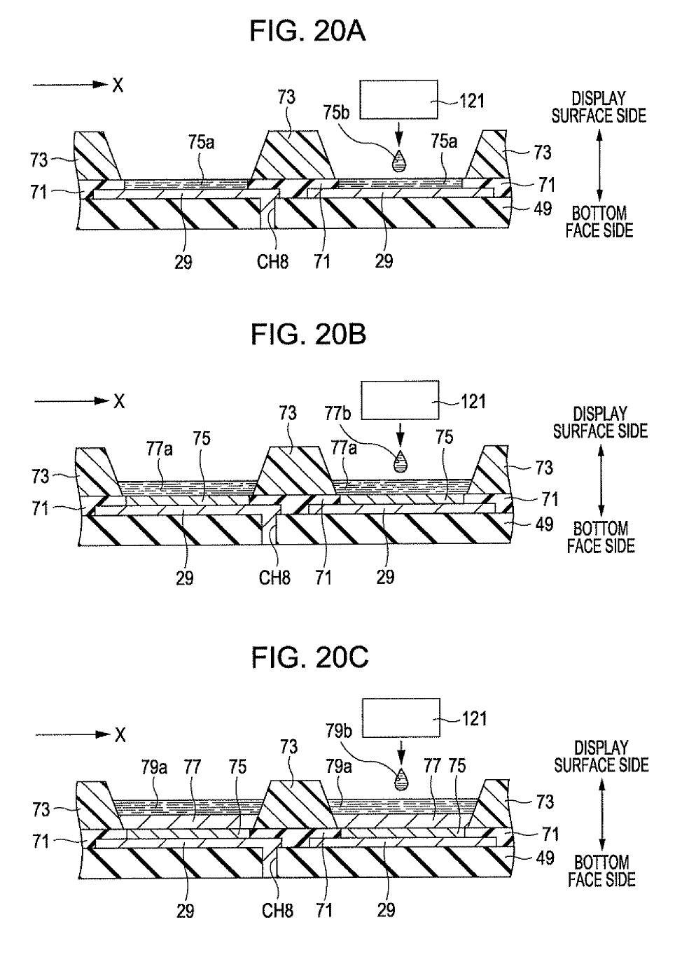

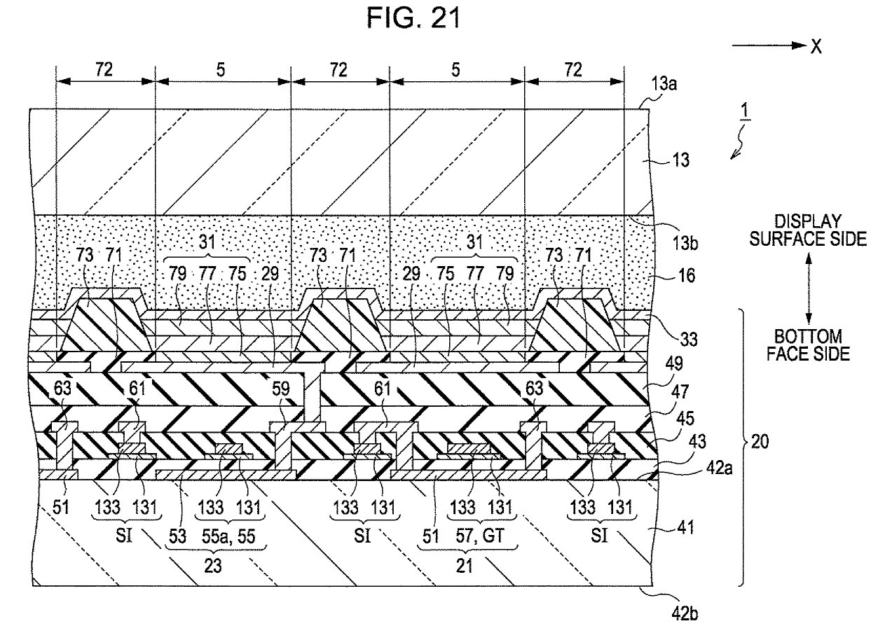

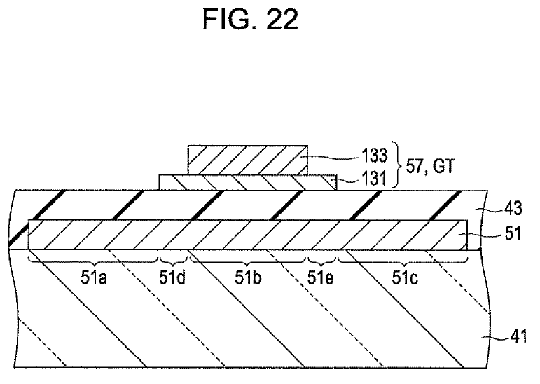

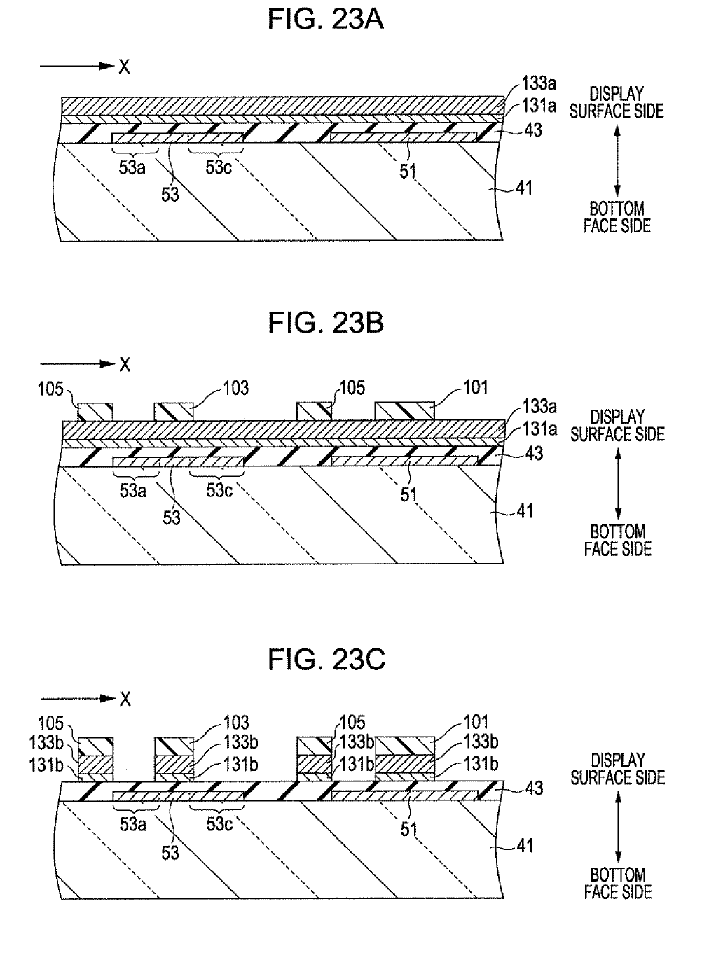

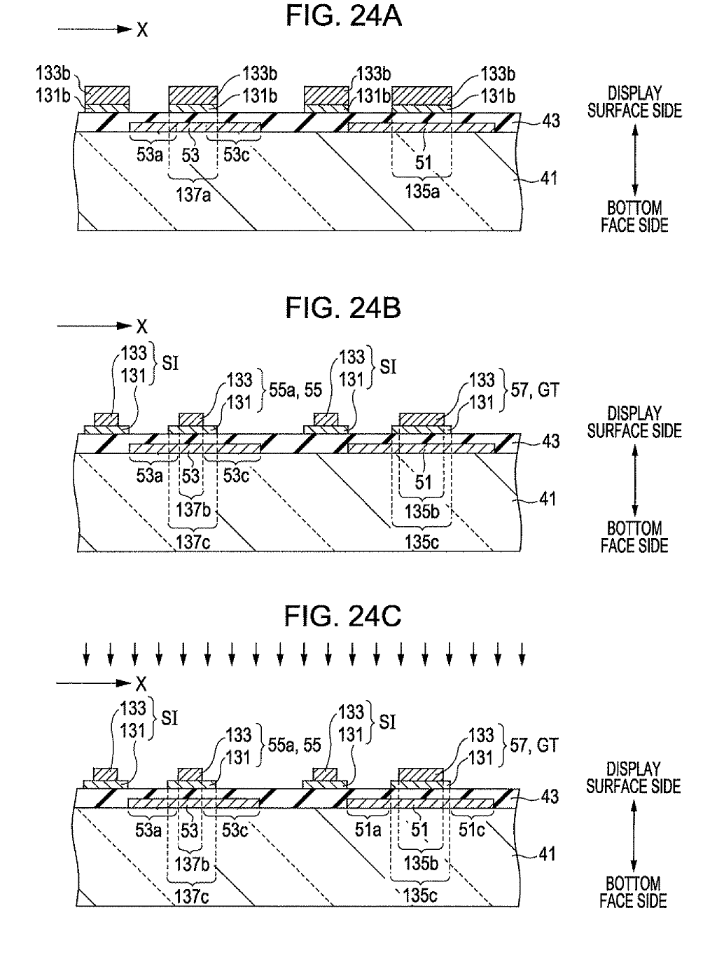

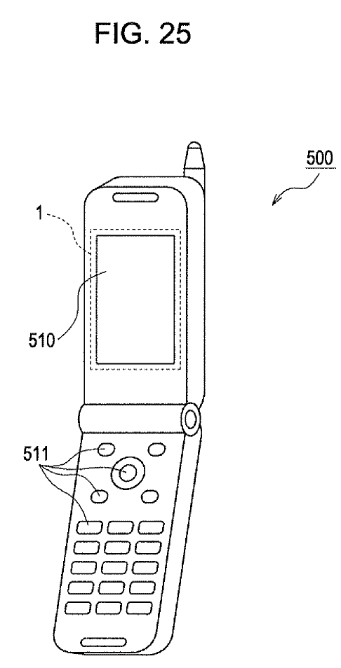

FIG. 17C is a diagram illustrating a step of producing the element substrate in the first Embodiment.

FIG. 17D is a diagram illustrating a step of producing the element substrate in the first Embodiment.

FIG. 18 is an enlarged view of the area XVIII in FIG. 17D.

FIG. 19A is a diagram illustrating a step of producing the element substrate in the first Embodiment.

FIG. 19B is a diagram illustrating a step of producing the element substrate in the first Embodiment.

FIG. 19C is a diagram illustrating a step of producing the element substrate in the first Embodiment.

FIG. 20A is a diagram illustrating a step of producing the element substrate in the first Embodiment.

FIG. 20B is a diagram illustrating a step of producing the element substrate in the first Embodiment.

FIG. 20C is a diagram illustrating a step of producing the element substrate in the first Embodiment.

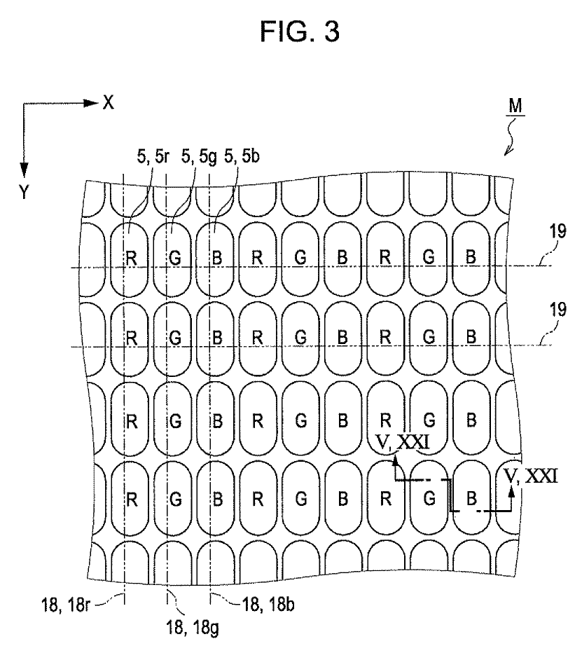

FIG. 21 is a cross-sectional view of a display apparatus according to a second Embodiment, taken along the line XXI-XXI in FIG. 3.

FIG. 22 is an enlarged view of the selecting transistor in FIG. 21.

FIG. 23A is a diagram illustrating a step of producing an element substrate in the second Embodiment.

FIG. 23B is a diagram illustrating a step of producing the element substrate in the second Embodiment.

FIG. 23C is a diagram illustrating a step of producing the element substrate in the second Embodiment.

FIG. 24A is a diagram illustrating a step of producing the element substrate in the second Embodiment.

FIG. 24B is a diagram illustrating a step of producing the element substrate in the second Embodiment.

FIG. 24C is a diagram illustrating a step of producing the element substrate in the second Embodiment.

FIG. 25 is a perspective view of electronic equipment to which the display apparatus according to the first or second Embodiment is applied.

### DESCRIPTION OF EXEMPLARY EMBODIMENTS

Embodiments of the invention will be described with reference to the drawings, using a display apparatus having organic EL devices as electro-optical devices thereof as examples.

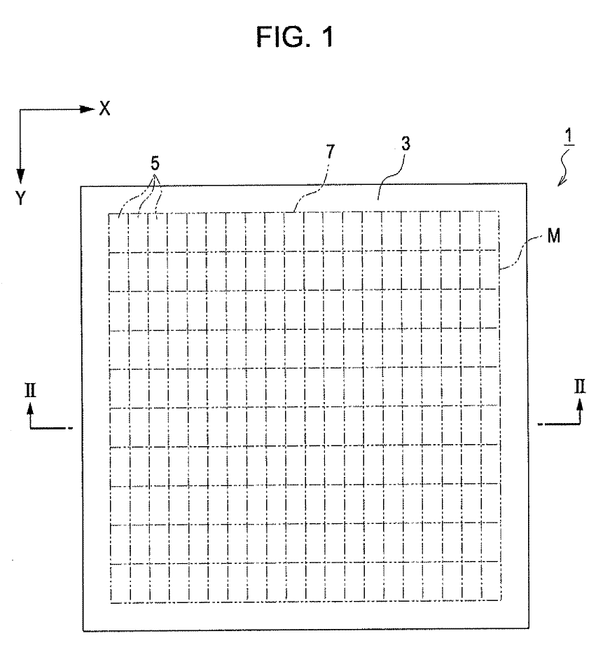

A display apparatus 1 according to a first Embodiment, as shown in FIG. 1 has a display surface 3.

The display apparatus 1 herein is provided with a plurality of pixels 5. The plurality of pixels 5 are aligned in a display region 7 in the X-direction and the Y-direction in the drawing to form a matrix M having the X-direction as the row direction and the Y-direction as the column direction. The display apparatus 1 can display an image on the display surface 3 by emitting light from selected pixels of the plurality of pixels 5 through the display surface 3 toward the outside of the display apparatus 1. The display region 7 is a region in which images can be displayed. In FIG. 1, for easier understanding of the structure, the pixels 5 are shown in a magnified scale and are reduced in number.

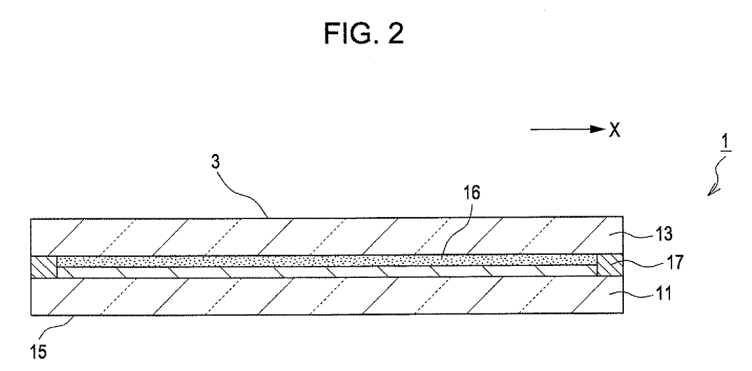

As shown in FIG. 2, which is a cross-sectional view taken along the line II-II in FIG. 1, the display apparatus 1 includes an element substrate 11 and a sealing substrate 13.

The element substrate 11 is provided with organic EL elements and other components described below that correspond to the respective pixels 5 on the display surface 3 side, that is, on the sealing substrate 13 side. The surface 15 opposite to the display surface 3 side of the element substrate 11 serves as the bottom face of the display apparatus 1. Hereinafter, the surface 15 is denoted as “bottom face 15”.

The sealing substrate 13 is disposed so as to face the element substrate 11 at the display surface 3 side of the element substrate 11. The element substrate 11 and the sealing substrate 13 are bonded with an adhesive 16. In the display apparatus 1, the organic EL elements are covered with the adhesive 16 from the display surface 3 side. Furthermore, a sealing material 17 surrounding the display region 7 inside the periphery of the display apparatus 1 seals between the element substrate 11 and the sealing substrate 13. That is, in the display apparatus 1, the organic EL elements and the adhesive 16 are sealed with the element substrate 11, the sealing substrate 13, and the sealing material 17.

The plurality of pixels 5 in the display apparatus 1 are each set, as shown in FIG. 3, such that light emitted from the display surface 3 has a red base (R), green base (G), or blue base (B) color. This means the plurality of pixels 5 constituting the matrix M include pixels 5r that emit light of R, pixels 5g that emit light of G, and pixels 5b that emit light of B.

Hereinafter, the term “pixel 5” and the terms “pixel 5r, pixel 5g, and pixel 5b” are distinctly used.

The color R is not limited to a pure red color and includes, for example, orange. The color G is not limited to a pure green color and includes, for example, blue-green and yellow-green. The color B is not limited to a pure blue color and includes, for example, violet-blue and blue-green. In another definition, the light having color R can be defined as light having a light wavelength peak in the range of a visible light region of 570 nm or more. The light having color G can be defined as light having a light wavelength peak in the range of 500 to 565 nm. The light having color B can be defined as light having a light wavelength peak in the range of 415 to 495 nm.

In the matrix M, a plurality of pixels 5 aligned along the Y-direction forms one pixel column 18, and a plurality of pixels 5 aligned along the X-direction forms one pixel row 19. The pixels 5 in one pixel column 18 are set such that the color of light is one of R, G, and B. This means the matrix N includes pixel columns 18r formed by a plurality of pixels 5r aligned along the Y-direction, pixel columns 18g formed by a plurality of pixels 5g aligned along the Y-direction, and pixel columns 18b formed by a plurality of pixels 5b aligned along the Y-direction. In the display apparatus 1, the pixel column 18r, the pixel column 18g, and the pixel column 18b, in this order, are repeatedly aligned along the X-direction.

Hereinafter, the term “pixel column 18” and the terms “pixel column 18r, pixel column 18g, and pixel column 18b” are distinctly used.

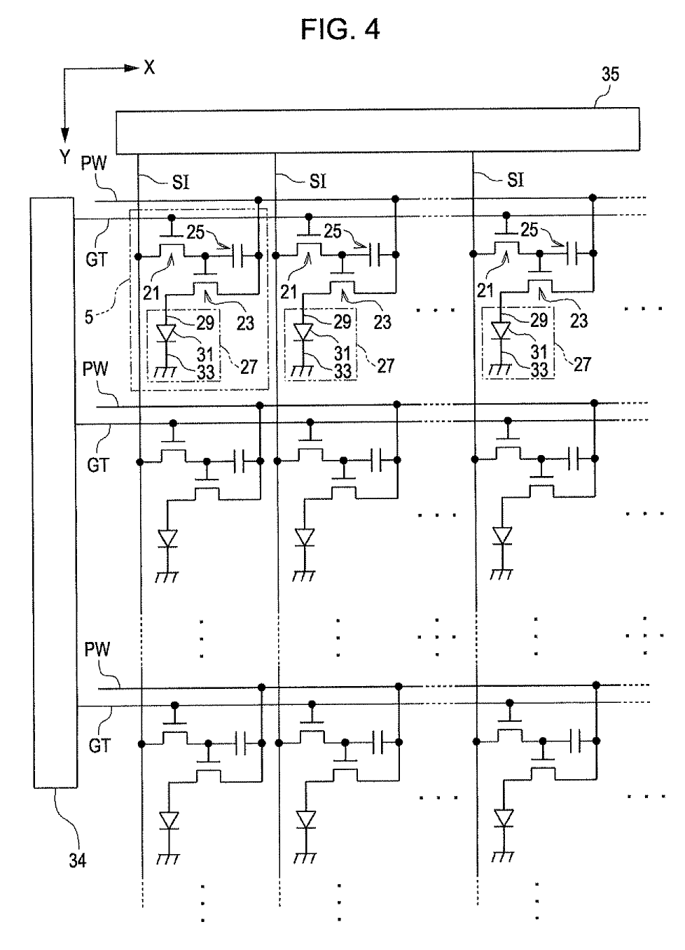

As shown in FIG. 4, which is the diagram showing the circuit structure, the display apparatus 1 includes a selecting transistor 21, a driving transistor 23, a capacitor element 25, and an organic EL element 27 per each pixel 5. The organic EL element 27 includes a pixel electrode 29, an organic layer 31, and a common electrode 33. The selecting transistor 21 and the driving transistor 23 are each composed of a TFT (thin film transistor) and each have a function as a switching element. Furthermore, the display apparatus 1 includes a scanning line driving circuit 34, a data line driving circuit 35, a plurality of scanning lines GT, a plurality of data lines Si, and a plurality of power wires PW.

The plurality of scanning lines GT are connected to the scanning line driving circuit 34 and are aligned in the Y-direction with distances between one another so as to extend in the X-direction.

The plurality of data lines SI are connected to the data line driving circuit 35 and are aligned in the X-direction with distances between one another so as to extend in the Y-direction.

The plurality of power wires PW are aligned in the Y-direction with distances between one another such that the power wires PW extend in the X-direction with distances from the corresponding scanning lines GT in the Y-direction.

The pixels 5 are each defined by the scanning lines GT and the data lines SI that intersect with one another. The scanning lines GT and the power wires PW each correspond to the pixel row 19 shown in FIG. 3, and the data lines SI each correspond to the pixel column 18 shown in FIG. 3.

As shown in FIG. 4, the gate electrode of each selecting transistor 21 is electrically connected to the corresponding scanning line GT. The source electrode of each selecting transistor 21 shown is electrically connected to the corresponding data line SI. The drain electrode of each selecting transistor 21 is electrically connected to the gate electrode of each driving transistor 23 and one electrode of each capacitor element 25.

The other electrode of the capacitor element 25 and the source electrode of the driving transistor 23 are electrically connected to the corresponding power wire PW.

The drain electrode of each driving transistor 23 is electrically connected to the pixel electrode 29. The pixel electrode 29 and the common electrode 33 form a pair of electrodes in which the pixel electrode 29 functions as an anode and the common electrode 33 functions as a cathode.

The common electrode 33 here is provided over the plurality of pixels 5 constituting the matrix M and functions over the plurality of pixels 5 as an electrode.

The organic layer 31 intervening between each pixel electrode 29 and the common electrode 33 is made of an organic material and has a structure including a light-emitting layer described below.

The selecting transistor 21 becomes in the ON state when a selection signal is supplied to the scanning line GT that is connected to this selecting transistor 21. On this occasion, the data line SI that is connected to this selecting transistor 21 supplies a data signal to make the driving transistor 23 to the ON state. The gate potential of the driving transistor 23 is maintained for a certain period of time by that the potential of the data signal is maintained in the capacitor element 25 for a certain period of time. With this, the ON state of the driving transistor 23 is maintained for a certain period of time. The data signal is generated as a potential corresponding to a gradation display.

When the driving transistor 23 is maintained in the ON state, an electric current corresponding to the gate potential of the driving transistor 23 flows from the power wire PW to the common electrode 33 via the pixel electrode 29 and the organic layer 31. Then, the light-emitting layer included in the organic layer 31 emits light having brightness corresponding to the amount of the electric current flowing in the organic layer 31. With this, a gradation display can be performed in the display apparatus 1.

The display apparatus 1 is a top-emission organic EL device in which the light-emitting layer included in the organic layer 31 emits light, and the light from the light-emitting layer is emitted from the display surface 3 through the sealing substrate 13. In the display apparatus 1, the display surface 3 side is also expressed as the upper side, and the bottom face 15 side is also expressed as the lower side.

In this Embodiment, an N-channel type TFT element is employed as the selecting transistor 21, and a P-channel type TFT element is employed as the driving transistor 23. The scanning line driving circuit 34 and the data line driving circuit 35 each have a complementary TFT element that is a combination of an N-channel type TFT element and a P-channel type TFT element.

The structures of the element substrate 11 and the sealing substrate 13 will now be described in detail.

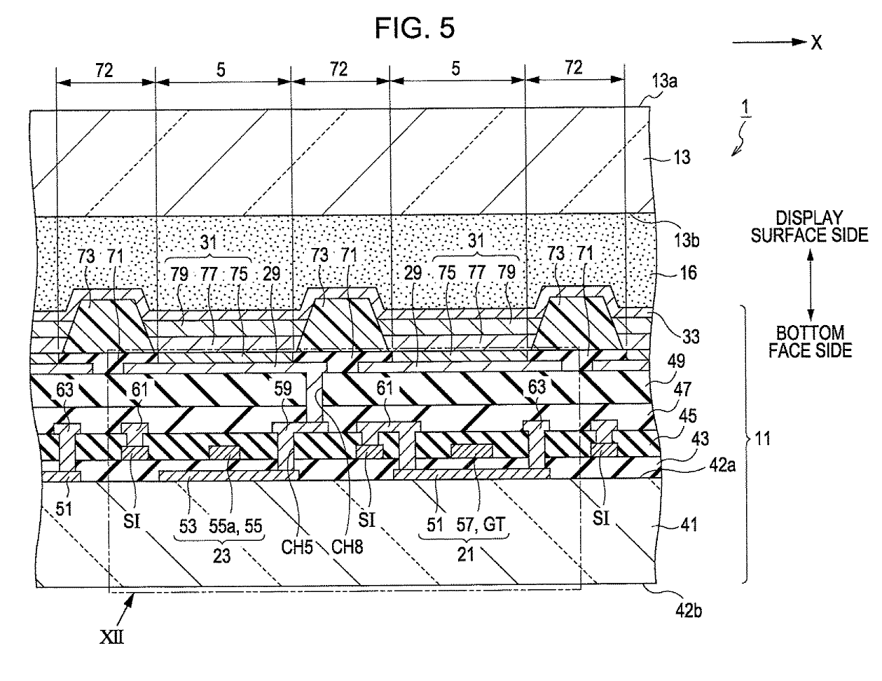

As shown in FIG. 5, which is a cross-sectional view taken along the line V-V in FIG. 3, the element substrate 11 includes a first substrate 41.

The first substrate 41 is made of a light-transmitting material such as glass or quartz and has a first surface 42a facing the display surface 3 side and a second surface 42b facing the bottom face 15 side. In the top-emission display apparatus 1, the first substrate 41 may be a silicone substrate.

On the first surface 42a of the first substrate 41, a gate-insulating film 43 is disposed. On the display surface 3 side of the gate-insulating film 43, an insulation film 45 is disposed. On the display surface 3 side of the insulation film 45, an insulation film 47 is disposed. On the display surface 3 side of the insulation film 47, an insulation film 49 is disposed.

On the first surface 42a of the first substrate 41, first semiconductor layers 51 each corresponding to the selecting transistor 21 of the pixel 5 and second semiconductor layers 53 each corresponding to the driving transistor 23 of the pixel 5 are provided.

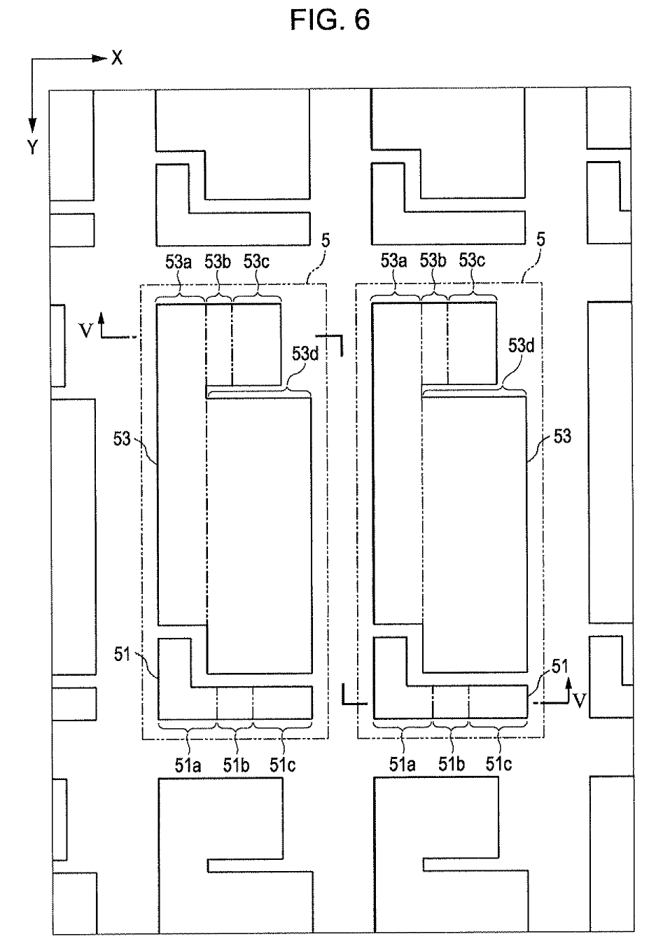

As shown in the plan view of FIG. 6, each pixel 5 includes the first semiconductor layer 51 and the second semiconductor layer 53. The cross-section shown in FIG. 5 corresponds to the cross-section taken along the line V-V in FIG. 6.

In each pixel 5, the first semiconductor layer 51 and the second semiconductor layer 53 are aligned so as to be adjacent to each other in the Y-direction with a distance therebetween in the Y-direction.

As shown in FIG. 6, the first semiconductor layer 51 includes a source region 51a, a channel region 51b, and a drain region 51c. The source region 51a, the channel region 51b, and the drain region 51c are aligned in the X-direction.

The second semiconductor layer 53 includes a source region 53a, a channel region 53b, a drain region 53c, and an electrode portion 53d. The source region 53a, the channel region 53b, and the drain region 53c are aligned in the X-direction. The electrode portion 53d is disposed so as to be adjacent to the channel region 53b and the drain region 53c in the Y-direction with a distance therebetween in the Y-direction. The electrode portion 53d and the source region 53a are adjacent to each other in a connecting state in the x-direction.

As shown in FIG. 5, the first semiconductor layer 51 and the second semiconductor layer 53 are covered with the gate-insulating film 43 from the display surface 3 side. The gate-insulating film 43 can be made of, for example, silicon oxide.

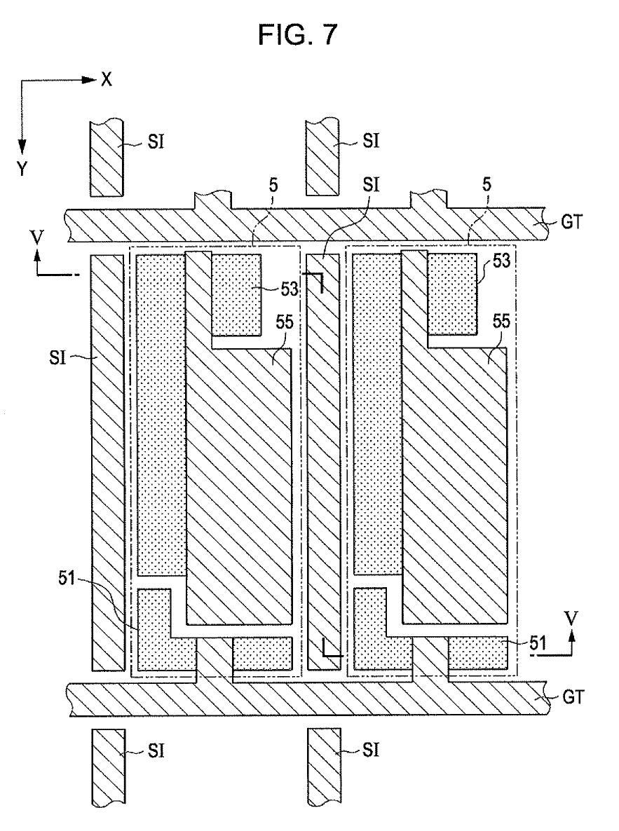

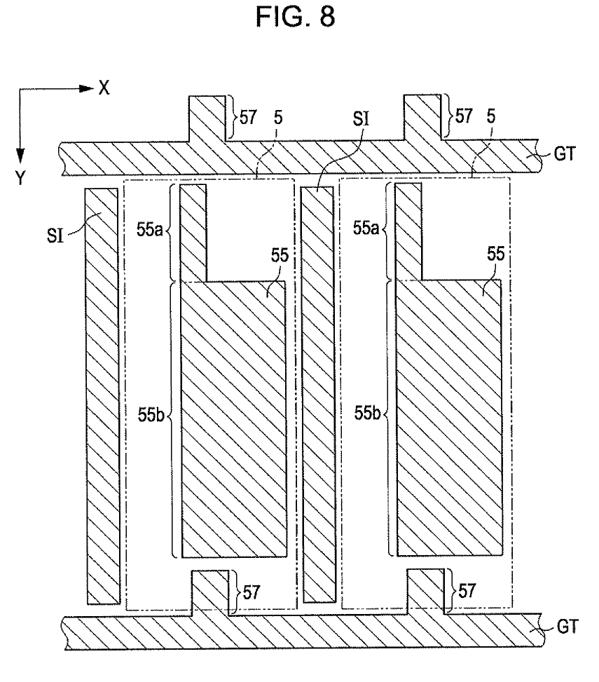

As shown in the plan view of FIG. 7, island electrodes 55 that overlap with the second semiconductor layers 53, the scanning lines GT, and the data lines SI are disposed on the display surface 3 side of the gate-insulating film 43. Furthermore, as shown in the plan view of FIG. 8, the island electrodes 55 each include a gate electrode portion 55a and an electrode portion 55b. The gate electrode portion 55a and the electrode portion 55b are adjacent to each other in the Y-direction in a connecting state.

The gate electrode portion 55a overlaps with the channel region 53b of the second semiconductor layer 53 shown in FIG. 6. The electrode portion 55b overlaps with the electrode portion 53d of the second semiconductor layer 53. The electrode portion 53d and the electrode portion 55b constitute part of the capacitor element 25.

As shown in FIG. 8, the scanning lines GT are each provided with gate electrode portions 57 branched in the Y-direction toward the corresponding pixels 5. The gate electrode portions 57 each overlap with the channel region 51b of the first semiconductor layer 51 shown in FIG. 6.

The island electrode 55 of each pixel 5 is adjacent to the data line SI corresponding to the pixel 5 in the X-direction.

The island electrodes 55, the scanning lines GT, and the data lines SI can be made of, for example, a metal such as aluminum, copper, molybdenum, tungsten, or chromium, or an alloy thereof. In this Embodiment, the island electrodes 55, the scanning lines GT, and the data lines SI are made of an aluminum alloy. As shown in FIG. 5, the gate electrode portions 55a (island electrodes 55), the gate electrode portions 57 (scanning lines GT), and the data lines SI are covered with the insulation film 45 from the display surface 3 side. The insulation film 45 may be made of a material such as silicon oxide.

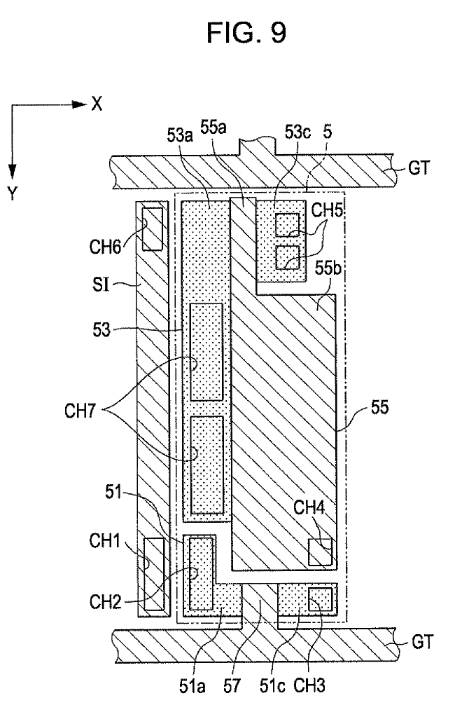

As shown in the plan view of FIG. 9, the insulation film 45 is provided with contact holes CH1, CH2, CH3, CH4, CH5, CH6, and CH7 so as to correspond to each pixel 5. The contact hole CH1 is provided at a position overlapping with the corresponding data line SI and facing the source region 51a of the first semiconductor layer 51 in the X-direction. The contact hole CH1 reaches the data line SI.

The contact hole CH2 is provided, so as to correspond to each source region 51a, at a position overlapping with the source region 51a and facing the contact hole CH1 in the X-direction. The contact hole CH2 reaches the source region 51a of the first semiconductor layer 51.

The contact hole CH3 is provided, so as to correspond to each drain region 51c, at a position overlapping with the drain region 51c. The contact hole CH3 reaches the drain region 51c of the first semiconductor layer 51.

The contact hole CH4 is provided, so as to correspond to each electrode portion 55b, at a position overlapping with the electrode portion 55b and facing the contact hole CH3 in the Y-direction. The contact hole CH4 reaches the electrode portion 55b.

Regarding the contact hole CH5, two contact holes CH5 are provided, so as to correspond to the drain region 53c of each second semiconductor layer 53, at a position overlapping with the drain region 53c. The contact holes CH5 reach the drain region 53c of the second semiconductor layer 53.

The contact hole CH6 is provided at a position overlapping with the corresponding data line SI and facing the gate electrode portion 55a with the source region 53a therebetween in the X-direction. The contact hole CH6 reaches the data line SI.

Regarding the contact hole CH7, two contact holes CH7 are provided, so as to correspond to each source region 53a, at a position overlapping with the source region 53a and facing the electrode portion 55b in the X-direction between the data line SI and the electrode portion 55b of the island electrode 55 in the plan view. The contact holes CH7 reach the source region 53a of the second semiconductor layer 53.

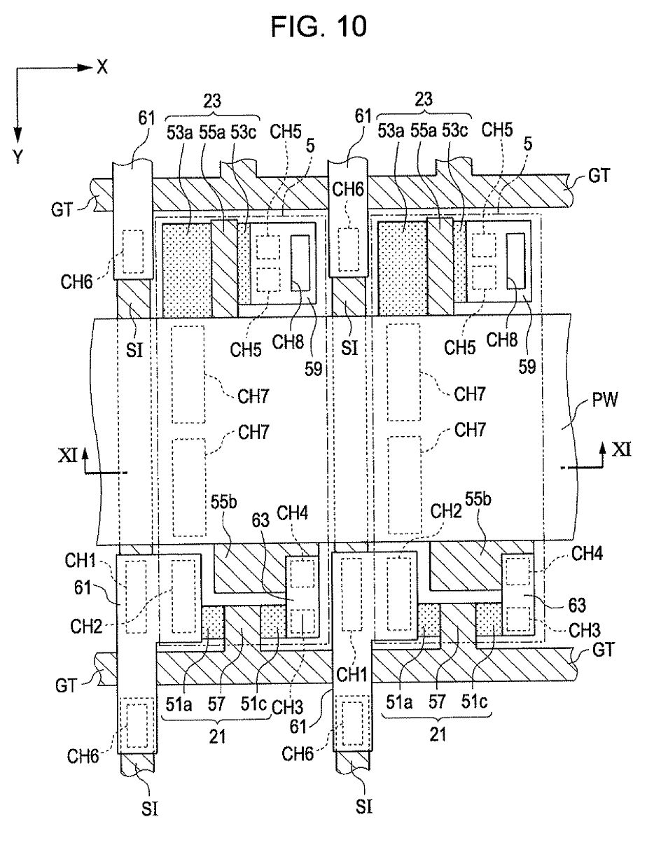

As shown in the plan view of FIG. 10, the power wires PW, drain electrodes 59, relay electrodes 61, and relay electrodes 63 are disposed on the display surface 3 side of the insulation film 45 that are provided with the contact holes CH1 to CH7.

The power wires PW each have a length running over the pixel rows 19 (FIG. 3) in the X-direction and have a width in the Y-direction, as shown in FIG. 10, over the two contact holes CH7 aligned in the Y-direction. Thus, each power wire PW covers the plurality of contact holes CH7 in each pixel row 19.

In each pixel 5, the power wire PW is located between the selecting transistor 21 and the driving transistor 23 in a plan view. In other words, the selecting transistor 21 and the driving transistor 23 face to each other in the Y-direction with the power wire PW therebetween. The source region 51a, the channel region 51b (FIG. 6), and the drain region 51c of the selecting transistor 21 are located at the outside of the power wire PW in a plan view. Part of the source region 53a, the channel region 53b (FIG. 6), and the drain region 53c of the driving transistor 23 are located at the outside of the power wire PW in a plan view.

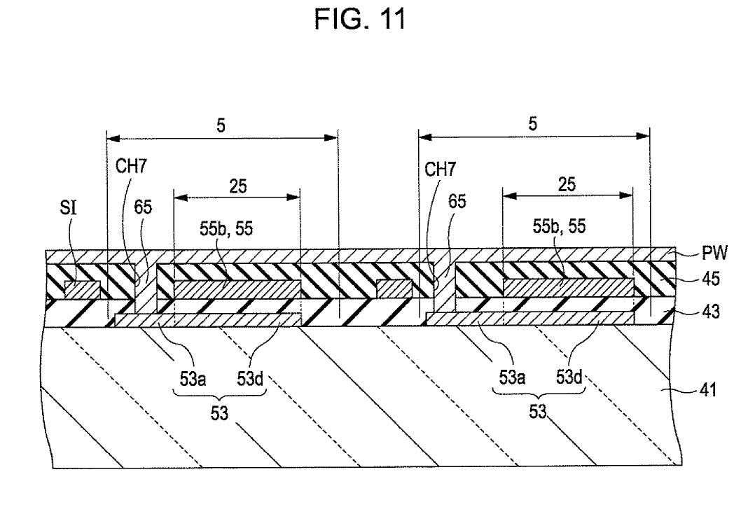

As shown in FIG. 11, which is a cross-sectional view taken along the line XI-XI in FIG. 10, the power wire PW reaches the source regions 53a of the second semiconductor layers 53 via the contact holes CH7. In the display apparatus 1, the portion from the power wire PW to the source region 53a via the contact hole CH7 is called a source electrode portion 65.

As described above, the contact holes CH7 are each provided, in a plan view, between the data line SI and the electrode portion 55b of the island electrode 55 corresponding to each pixel 5. Therefore, each source electrode portion 65 is located, in a plan view, between the data line SI and the electrode portion 55b of the island electrode 55 corresponding to each pixel 5.

The capacitor element 25 is formed at the region where the power wire PW, the electrode portion 55b of the island electrode 55, and the electrode portion 53d of the second semiconductor layer 53 overlap with one another in a plan view. Therefore, it can be regarded that the capacitor element 25 is provided between the first substrate 41 and the power wire PW. The electrode portion 55b, the channel region 53b, and the power wire PW constitute part of the capacitor element 25.

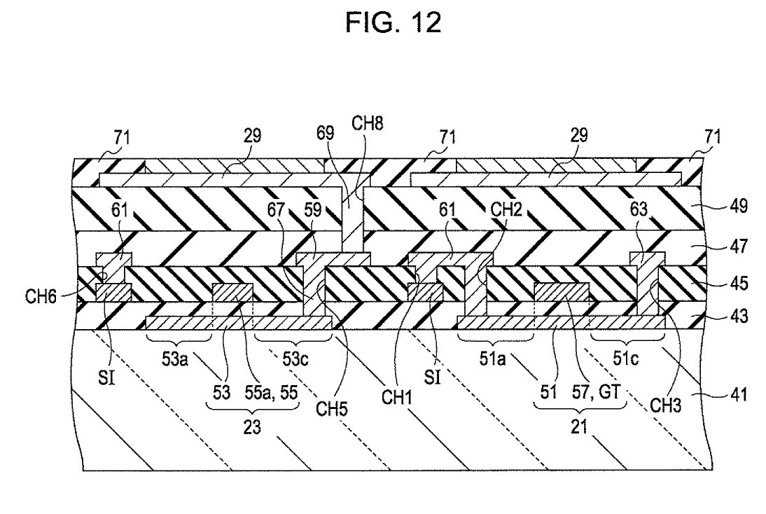

As shown in FIG. 10, the drain electrode 59 is provided to each pixel 5 and covers the contact hole CH5. As shown in FIG. 12, which is an enlarged view taken along the line XII-XII in FIG. 5, the drain electrode 59 reaches the drain region 53c of the second semiconductor layer 53 via the contact hole CH5. In the display apparatus 1, the portion from the drain electrodes 59 to the drain region 53c via the contact hole CH5 is called a connecting portion 67.

As shown in FIG. 10, each pixel 5 is provided with the relay electrode 61. Each relay electrode 61 extends from the contact hole CH1 of one of two pixels 5 adjacent to each other in the Y-direction to the contact hole CH6 of the other of the two pixels 5. In each pixel 5, the relay electrode 61 extends from the contact hole CH1 to the contact hole CH2.

The relay electrode 61 covers the contact holes CH1 and CH2 of one of two pixels 5 adjacent to each other in the Y-direction and the contact hole CH6 of the other of the two pixels 5. With this, two data lines SI adjacent to each other in the Y-direction are electrically connected through the relay electrode 61.

Furthermore, the data line SI is electrically connected to the source region 51a of the first semiconductor layer 51 corresponding to the data line SI through the relay electrode 61.

Each pixel 5 is provided with the relay electrode 63. Each relay electrode 63 extends from the contact hole CH3 to the contact hole CH4 of each pixel 5. The relay electrode 63 covers these contact holes CH3 and CH4 at the outside of the periphery of the power wire PW. With this, in each pixel 5, the drain region 51c of the first semiconductor layer 51 and the electrode portion 55b of the island electrode 55 are electrically connected through the relay electrode 63 at the outside of the periphery of the power wire PW.

The power wires PW, the drain electrodes 59, the relay electrodes 61, and the relay electrodes 63 can be made of, for example, a metal such as aluminum, copper, molybdenum, tungsten, or chromium, or an alloy thereof. As shown in FIG. 5, the drain electrodes 59, the relay electrodes 61, and the relay electrodes 63 are covered with the insulation film 47 from the display surface 3 side. Furthermore, the power wires PW are also covered with the insulation film 47 from the display surface 3 side.

The insulation film 47 is covered with the insulation film 49 from the display surface 3 side.

The insulation film 47 and the insulation film 49 are provided with contact holes CH8. As shown in FIG. 10, each pixel 5 is provided with the contact hole CH8. The contact hole CH8 is provided at a region overlapping with the drain electrode 59 and reaches the drain electrode 59.

The drain electrode 59 extends toward the side opposite to the gate electrode portion 55a in the X-direction. The contact hole CH8 overlaps in a plan view with the extended portion of the drain electrode 59. Consequently, the contact hole CH5 and the contact hole CH8 do not overlap with each other in a plan view, but they may overlap with each other in a plan view.

As shown in FIG. 5, the pixel electrode 29 is provided for each pixel 5 on the display surface 3 side of the insulation film 49 having the contact holes CH8.

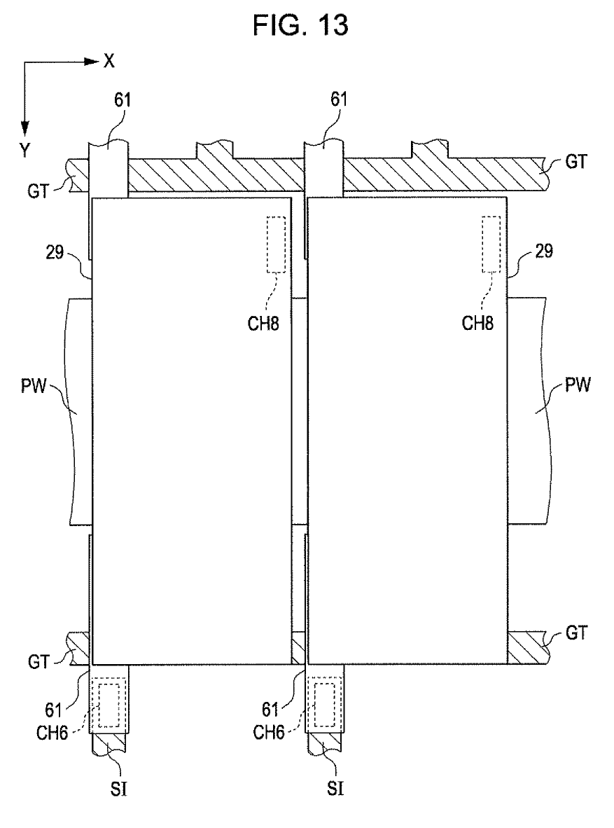

In each pixel 5, as shown in the plan view of FIG. 13, the pixel electrode 29 extends, in the Y-direction, over the scanning line GT corresponding to the pixel 5 and the contact hole CH8 and extends, in the X-direction, over the contact hole CH8 and the data line SI corresponding to the pixel 5. The pixel electrode 29 covers the contact hole CH8.

In the display apparatus 1, as shown in FIG. 12, the portion from the pixel electrode 29 to the drain electrode 59 via the contact hole CH8 is called a connecting portion 69.

The pixel electrode 29 can be made of a metal having light-reflecting properties, such as silver, aluminum, or copper, or an alloy thereof. When the pixel electrode 29 is used as an anode, it is preferable to be made of a material having a relatively high photoelectric threshold, such as silver or platinum. Furthermore, the pixel electrode 29 can be made of ITO (indium-tin-oxide) or indium-zinc-oxide by employing a structure in which a material having light-reflecting properties is disposed between the pixel electrode 29 and the first substrate 41.

The insulation film 47 and the insulation film 49 can be made of, for example, silicon oxide, silicon nitride, or an acrylic resin.

As shown in FIG. 5, an insulation film 71 is provided between the adjacent pixel electrodes 29 over each region 72 to divide the pixels 5 from one another. The insulation film 71 is formed of a material having light-transmitting properties such as silicon oxide, silicon nitride, or an acrylic resin. The insulation film 71 is provided in a grid-like form over the display region 7 (FIG. 1). Consequently, the display region 7 is divided into regions of the plurality of pixels 5 by the insulation film 71. The pixel electrode 29 overlaps in a plan view with the corresponding pixel 5 region surrounded by the insulation film 71.

On the display surface 3 side of the insulation film 71, a light-shielding film 73 is disposed so as to surround the region of each pixel 5. The light-shielding film 73 is made of an acrylic resin containing a material having high light-absorbing properties, such as carbon black or chromium, or a resin such as polyimide and is in a grid-like form in a plan view.

On the display surface 3 side of the pixel electrode 29, the organic layer 31 is disposed within the region surrounded by the light-shielding film 73.

The organic layer 31 is provided to each pixel 5 and includes a hole-injecting layer 75, a hole-transporting layer 77, and a light-emitting layer 79.

The hole-injecting layer 75 is made of an organic material and is disposed on the display surface 3 side of the pixel electrode 29 in the region surrounded by the insulation film 71 in a plan view.

The organic material for the hole-injecting layer 75 can be a mixture of a polythiophene derivative such as 3,4-polyethylenedioxythiophene (PEDOT) and, for example, polystyrene sulfonic acid (PSS). Furthermore, the organic material of the hole-injecting layer 75 can be polystyrene, polypyrrole, polyaniline, polyacetylene, or a derivative thereof.

The hole-transporting layer 77 is made of an organic material and is disposed on the display surface 3 side of the hole-injecting layer 75 in the region surrounded by the light-shielding film 73 in a plan view.

The organic material for the hole-transporting layer 77 can have, for example, a structure containing a triphenylamine-based polymer such as TFB denoted as the following compound 1:

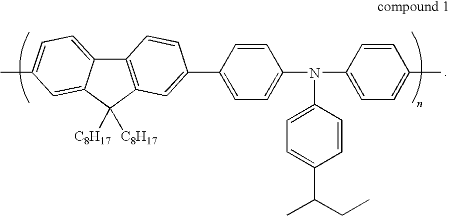

The light-emitting layer 79 is made of an organic material and is disposed on the display surface 3 side of the hole-transporting layer 77 in the region surrounded by the light-shielding film 73 in a plan view.

The organic material of the light-emitting layer 79 corresponding to the pixel 5r of R can be, for example, a mixture of a perylene dye and F8 (polydioctylfluorene) denoted as the following compound 2:

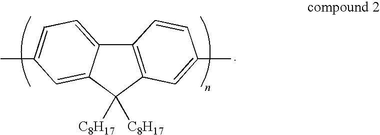

The organic material of the light-emitting layer 79 corresponding to the pixel 5g of G can be, for example, a mixture of TFB denoted as the above-mentioned compound 1, F8 denoted as the above-mentioned compound 2, and F8BT denoted as the following compound 3:

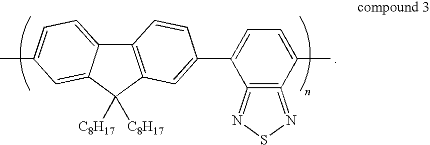

The organic material of the light-emitting layer 79 corresponding to the pixel 5b of B can be, for example, F8 denoted as the above-mentioned compound 2.

As shown in FIG. 5, the common electrode 33 is provided on the display surface 3 side of the organic layer 31. The common electrode 33 is made of, for example, a material having light-transmitting properties, such as ITO or indium-zinc-oxide, or a thin film of a material that can have light-transmitting properties when it is in a thin-film form, such as magnesium-silver. The common electrode 33 covers the organic layer 31 and the light-shielding film 73 from the display surface 3 side over the plurality of pixels 5.

In the display apparatus 1, the light-emitting region in each pixel 5 can be defined as a region where the pixel electrode 29, the organic layer 31, and the common electrode 33 overlap with one another in a plan view. Furthermore, a group of elements constituting the light-emitting region in each pixel 5 can be defined as one organic EL element 27. In the display apparatus 1, each organic EL element 27 has a structure including one pixel electrode 29, one organic layer 31, and the common electrode 33 corresponding to one pixel 5.

The sealing substrate 13 is made of a material having light-transmitting properties, such as glass or quartz, and has an outward surface 13a facing the display surface 3 side and an opposing surface 13b facing the bottom face 15 side.

The element substrate 11 and the sealing substrate 13 having the above-described structures are bonded by bonding the common electrode 33 of the element substrate 11 and the opposing surface 13b of the sealing substrate 13 with the adhesive 16.

In the display apparatus 1, the sealing material 17 shown in FIG. 2 is disposed between the first surface 42a of the first substrate 41 shown in FIG. 5 and the opposing surface 13b of the sealing substrate 13. That is, in the display apparatus 1, the organic EL elements 27 and the adhesive 16 are sealed with the first substrate 41, the sealing substrate 13, and the sealing material 17. The sealing material 17 may be provided between the opposing surface 13b and the common electrode 33. In such a case, it can be assumed that the organic EL elements 27 and the adhesive 16 are sealed with the element substrate 11, the sealing substrate 13, and the sealing material 17.

In the display apparatus 1 having the above-described structure, the display is controlled by emitting the light-emitting layer 79 with respect to each pixel 5. The state of light emission of the light-emitting layer 79 can be modified with respect to each pixel 5 by controlling the electric current flowing in each organic layer 31 with the driving transistor 23.

The scanning lines GT are each supplied with control signals in a line sequential manner. The data lines SI are each supplied with image signals as parallel signals.

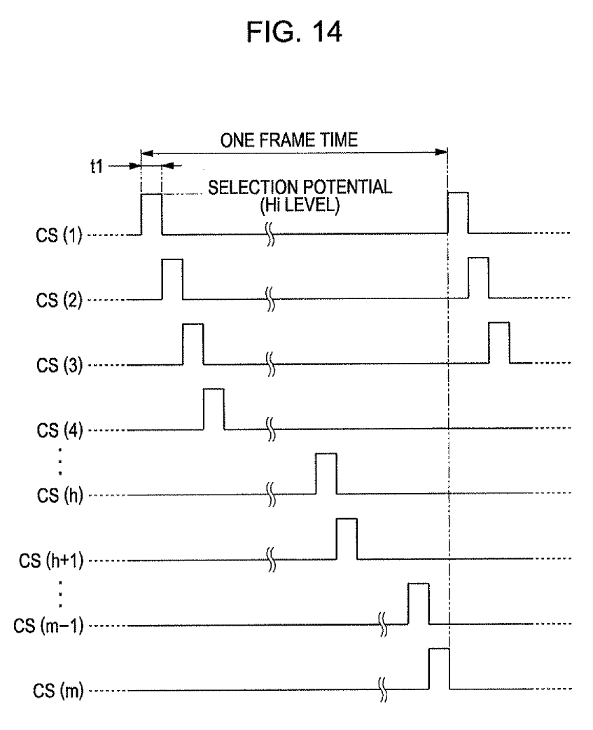

Each control signal CS supplied to each scanning line GT, as shown in FIG. 14, is maintained at a selection potential of Hi level for a time t1 that is shorter than one frame time only once in the frame time. Only a control signal CS corresponding to one scanning line GT can become the selection potential at a certain time.

When a scanning line GT becomes the selection potential, the selecting transistors 21 of the plurality of pixels 5 corresponding to this scanning line GT become in the ON state. On this occasion, the image signals supplied to the plurality of data lines SI are supplied to the gate electrode portions 55a and the electrode portions 55b (FIG. 10) of the driving transistors 23 through the selecting transistors 21. That is, in each pixel 5, the gate electrode portion 55a and the electrode portion 55b have a potential according to the potential of the image signal.

On this occasion, an electric current according to the potential of the gate electrode portion 55a of the driving transistor 23 flows into the drain region 53c from the power wire PW through the source region 53a and the channel region 53b.

Then, the electric current from the power wire PW flows into the organic layer 31 (FIG. 5) through the drain electrode 59 and the pixel electrode 29.

At the same time, electric charge is accumulated between the electrode portion 55b and the power wire PW (FIG. 11) and between the electrode portion 55b and the electrode portion 53d. Therefore, the potential of the gate electrode portion 55a of the driving transistor 23 is maintained for a certain period of time, As a result, the electric current continues to flow in the organic layer 31 during the potential of the gate electrode portion 55a is maintained.

Thus, in the display apparatus 1, since an electric current according to the potential of an image signal flows in the organic layer 31, the brightness of light from the light-emitting layer 79 can be controlled according to the potential of an image signal with respect to each pixel 5. With this, in the display apparatus 1, a gradation display can be performed.

Next, a method for producing the display apparatus 1 will be described.

The method for producing the display apparatus 1 is classified roughly into a process of producing the element substrate 11 and a process of assembling the display apparatus 1.

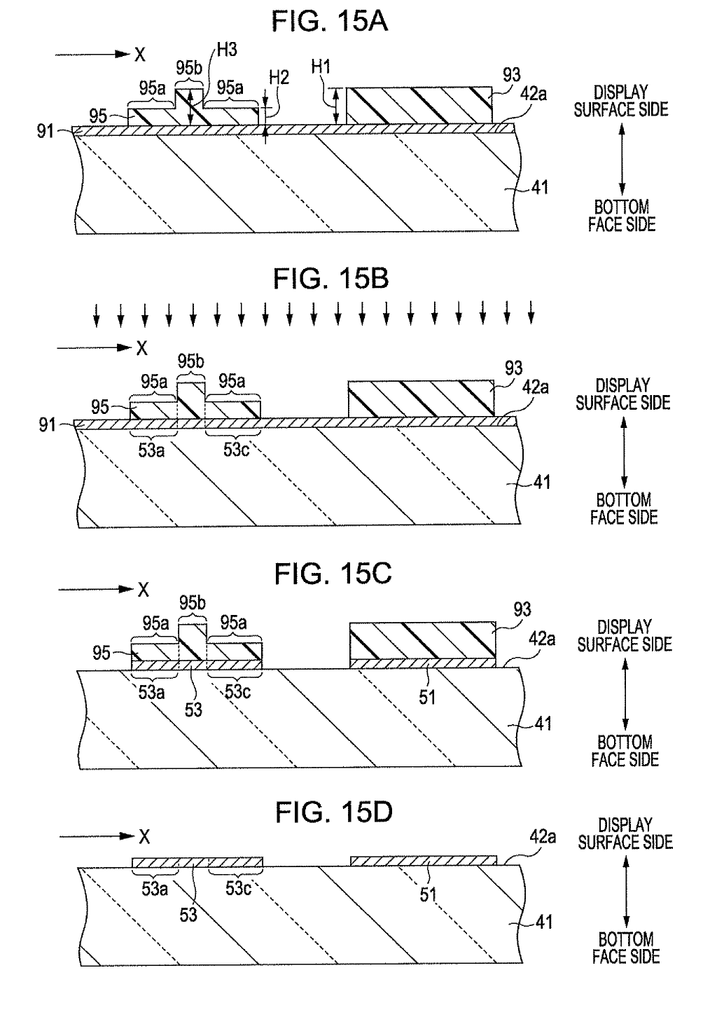

In the process of producing the element substrate 11, as shown in FIG. 15A, first, a silicon film 91 is formed on the first surface 42a of the first substrate 41. The silicon film 91 is made of polycrystalline silicon. In the process of forming the silicon film 91, an amorphous silicon film is formed using, for example, disilane or monosilane as a raw material gas by a CVD technique. Then, the amorphous silicon is converted to polycrystalline silicon by subjecting the amorphous silicon film to, for example, laser annealing.

After the formation of the silicon film 91, resist patterns including a first resist pattern 93 and a second resist pattern 95 are formed on the display surface 3 side of the silicon film 91. The first resist pattern 93 and the second resist pattern 95 are positive resist compositions. In this Embodiment, the first resist pattern 93 has a thickness H1. The second resist pattern 95 includes a first region 95a having a thickness H2 and a second region 95b having a thickness H3. The thickness H2 is smaller than the thickness H1. The thickness H3 is larger than the thickness H2. The second resist pattern 95 having the above-described structure can be formed by subjecting a resist film to, for example, multiple tone exposure using a grey-tone mask, a half-tone mask, or the like.

After the formation of the first resist pattern 93 and the second resist pattern 95, as shown in FIG. 15B, a P-type impurity is implanted into the silicon film 91. As the P-type impurity, an element such as boron can be used. The implantation can be performed under conditions, for example, a dose (implantation concentration) of about 1×10¹⁵ to 8×10¹⁵/cm² and an acceleration energy of about 45 keV.

In the step of implanting the P-type impurity, the impurity is inhibited by the first resist pattern 93 from reaching the silicon film 91 at the region where the first resist pattern 93 overlaps in a plan view with the silicon film 91. The impurity is also inhibited by the second region 95b of the second resist pattern 95 from reaching the silicon film 91 at the region where the second region 95b of the second resist pattern 95 overlaps in a plan view with the silicon film 91, but the P-type impurity can be implanted through the first region 95a of the second resist pattern 95 into the silicon film 91 at the region where the first region 95a of the second resist pattern 95 overlaps in a plan view with the silicon film 91.

Consequently, the source region 53a and the drain region 53c can be formed in the silicon film 91 at a region where the first region 95a of the second resist pattern 95 overlaps in a plan view with the silicon film 91. The concentration of the impurity in the source region 53a and the drain region 53c is lower than that in the region not having the mask of the first resist pattern 93 or the second resist pattern 95. The impurity concentrations in the silicon film 91 at the regions where the first resist pattern 93 or the second region 95b of the second resist pattern 95 overlaps in a plan view with the silicon film 91 are significantly lower than that of the source region 53a and the drain region 53c.

After the step of implanting the P-type impurity, the silicon film 91 is subjected to etching treatment using the first resist pattern 93 and the second resist pattern 95 as resist masks. By doing so, as shown in FIG. 15C, a first semiconductor layer 51 can be formed at the region where the silicon film 91 overlaps in a plan view with the first resist pattern 93, and a second semiconductor layer 53 is formed at the region where the silicon film 91 overlaps in a plan view with the second resist pattern 95.

Then, as shown in FIG. 15D, the first resist pattern 93 and the second resist pattern 95 are removed.

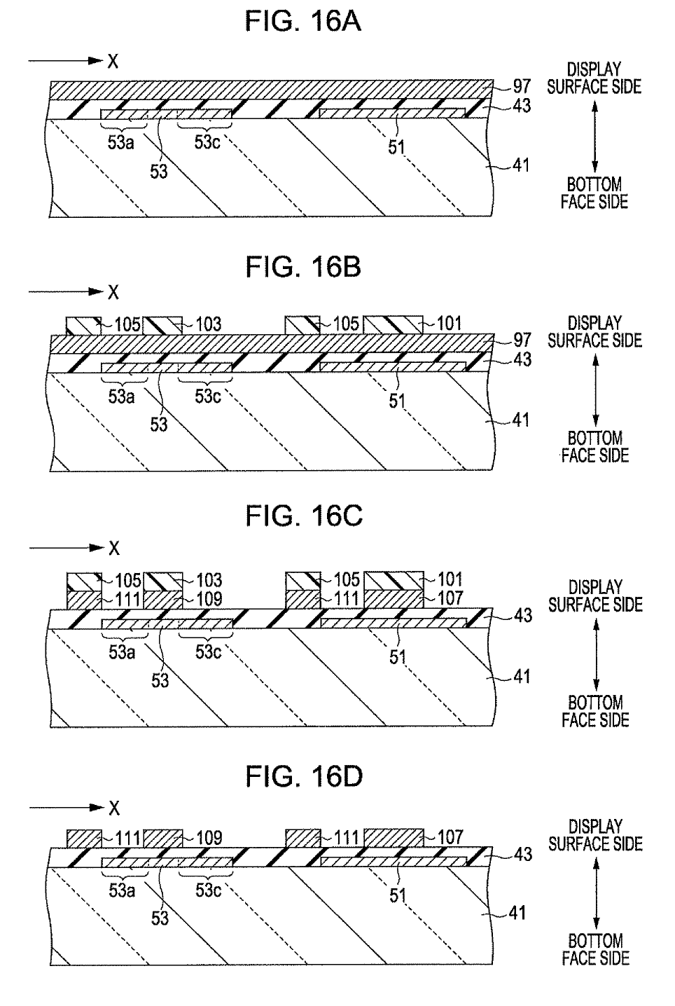

Then, as shown in FIG. 16A, a gate-insulating film 43 that covers the first semiconductor layer 51 and the second semiconductor layer 53 from the display surface 3 side is formed on the display surface 3 side of the first substrate 41. The gate-insulating film 43 can be formed by, for example, applying a CVD technique.

Then, an electrically conductive film 97 is formed on the display surface 3 side of the gate-insulating film 43. The electrically conductive film 97 is made of, for example, a metal such as aluminum, copper, molybdenum, tungsten, or chromium, or an alloy thereof and can be formed by applying a sputtering technique. In this Embodiment, the electrically conductive film 97 is made of an aluminum alloy.

Then, as shown in FIG. 16B, resist patterns including a third resist pattern 101, an fourth resist pattern 103, and a fifth resist pattern 105 are formed on the display surface 3 side of the electrically conductive film 97. The third resist pattern 101 is formed so as to overlap in a plan view with the first semiconductor layer 51. The fourth resist pattern 103 is formed so as to overlap in a plan view with the second semiconductor layer 53. The fifth resist pattern 105 is formed so as to overlap in a plan view with the data line SI (FIG. 8).

Then, the electrically conductive film 97 is subjected to etching treatment using the third resist pattern 101, the fourth resist pattern 103, and the fifth resist pattern 105 as resist masks. By doing so, as shown in FIG. 16C, a first electrically conductive pattern 107 can be formed at the region where the third resist pattern 101 overlaps in a plan view with the electrically conductive film 97; a second electrically conductive pattern 109 can be formed at the region where the fourth resist pattern 103 overlaps in a plan view with the electrically conductive film 97; and a third electrically conductive pattern 111 can be formed at the region where the fifth resist pattern 105 overlaps in a plan view with the electrically conductive film 97. In the etching treatment on this occasion, for example, dry etching treatment using a chlorine-containing gas as an etchant can be employed.

Then, as shown in FIG. 16D, the third resist pattern 101, the fourth resist pattern 103, and the fifth resist pattern 105 are removed.

Then, as shown in FIG. 17A, an N-type impurity is implanted into the first semiconductor layer 51 using the first electrically conductive pattern 107 as a mask. As the N-type impurity, an element such as phosphorus or arsenic can be used. The implantation can be performed under conditions, for example, a dose (implantation concentration) of about 2×10¹⁵/cm² and an acceleration energy of about 50 keV.

By doing so, as shown in FIG. 17B, the source region 51a and the drain region 51c can be formed in the first semiconductor layer 51 at a region outside the first electrically conductive pattern 107 in a plan view.

The region where the first semiconductor layer 51 and the first electrically conductive pattern 107 overlap with each other in a plan view is called a first superimposed region 113a, and the region where the second semiconductor layer 53 and the second electrically conductive pattern 109 overlap with each other in a plan view is called a second superimposed region 115a. The second superimposed region 115a overlaps in a plan view with part of the source region 53a and part of the drain region 53c.

In the step of implanting the N-type impurity, the impurity is inhibited by the first electrically conductive pattern 107 from reaching the first semiconductor layer 51 at the region in the first superimposed region 113a in a plan view. The impurity is also inhibited by the second electrically conductive pattern 109 from reaching the second semiconductor layer 53 at the region in the second superimposed region 115a in a plan view, but the N-type impurity can be implanted into the second semiconductor layer 53 at a region outside the second superimposed region 115a in a plan view.

Then, the first electrically conductive pattern 107, the second electrically conductive pattern 109, and the third electrically conductive pattern 111 are subjected to etching treatment. The etching treatment on this occasion is isotropic etching and wet etching. As an etchant in the wet etching, for example, TMAH (tetramethyl ammonium hydroxide) or a mixed acid of phosphoric acid, nitric acid, and acetic acid can be employed, The etching treatment on this occasion can be the dry etching described above, but the wet etching can exhibit an effect of washing particles and is therefore preferred.

By the etching treatment of the first electrically conductive pattern 107, the second electrically conductive pattern 109, and the third electrically conductive pattern 111, as shown in FIG. 17C, the gate electrode portion 57 (scanning line GT), the gate electrode portion 55a (island electrode 55), and the data line SI can be formed. By this etching treatment, the first superimposed region 113a is reduced to a first superimposed region 113b, and the second superimposed region 115a is reduced to a second superimposed region 115b.

After the etching treatment, a structure in which the gate electrode portion 55a (island electrode 55) overlaps in a plan view with part of the source region 53a and part of the drain region 53c can be also employed. By doing so, characteristic degradation caused by the N-type impurity in a second implantation step described below can be suppressed.

Then, as shown in FIG. 17D, an N-type impurity is implanted into the first semiconductor layer 51 using the gate electrode portion 57 as a mask.

The implantation of the N-type impurity in this occasion is called the second implantation step, and the former implantation of the N-type impurity is called the first implantation step.

The dose (implantation concentration) in the second implantation step is different from that in the first implantation step. In this Embodiment, the dose (implantation concentration) in the second implantation step is lower than that in the first implantation step.

The second implantation step can be performed under conditions, for example, a dose (implantation concentration) of about 2×10¹³ to 2×10¹⁴/cm² and an acceleration energy of about 60 keV.

In the second implantation step, as shown in FIG. 18, which is an enlarged view of the area XVIII in FIG. 17D, an LDD region 51d that is a region whose concentration of the N-type impurity is lower than that of the source region 51a can be formed between the source region 51a and the first superimposed region 113b. Similarly, an LDD region 51e that is a region whose concentration of the N-type impurity is lower than that of the drain region 51c can be formed between the drain region 51c and the first superimposed region 113b.

Furthermore, the channel region 51b that overlaps in a plan view with the gate electrode portion 57 can be formed between the LDD region 51d and the LDD region 51e.

In the source region 53a and the drain region 53c of the second semiconductor layer 53, the N-type impurity is implanted by the two times of implantation of the N-type impurity. The doses (implantation concentrations) in these two implantation steps are lower than that in the step implanting the P-type impurity. Consequently, characteristic degradation of the driving transistor 23, which is a P-channel type TFT element, can be significantly suppressed.

After the second implantation step, as shown in FIG. 19A, an insulation film 45 that covers the gate electrode portion 57 (scanning line GT), the gate electrode portion 55a (island electrode 55), and the data line SI from the display surface 3 side is formed on the display surface 3 side of the gate-insulating film 43. The insulation film 45 can be formed by applying, for example, a CVD technique.

Then, the contact holes CH1 to CH6 are formed in the gate-insulating film 43 and the insulation film 45. On this occasion, the contact hole CH7 (FIG. 9) is also formed.

Then, as shown in FIG. 19B, the relay electrode 61 and the relay electrode 63 are formed on the display surface 3 side of the insulation film 45. On this occasion, the power wire PW shown in FIG. 10 and the drain electrodes 59 are also formed.

Then, as shown in FIG. 19B, an insulation film 47 that covers the relay electrodes 61, the relay electrodes 63, the power wire PW, and the drain electrode 59 from the display surface 3 side is formed on the display surface 3 side of the insulation film 45.

Then, an insulation film 49 is formed on the display surface 3 side of the insulation film 47.

When the insulation film 47 and the insulation film 49 will be made of an inorganic material such as silicon oxide or silicon nitride, they can be formed by applying, for example, a CVD technique. When the insulation film 47 and the insulation film 49 will be made of an organic material such as an acrylic resin, they can be formed by applying, for example, a spin coat technique.

Then, the contact hole CH8 is formed in the insulation film 47 and the insulation film 49.

Then, as shown in FIG. 19C, a pixel electrode 29 is formed on the display surface 3 side of the insulation film 49.

Then, an insulation film 71 is formed at the periphery of the pixel electrode 29 and the region overlapping with the insulation film 49 (shown in FIG. 5 as the region 72) in a plan view.

When the insulation film 71 will be made of an inorganic material such as silicon oxide or silicon nitride, first, an inorganic film is formed by applying, for example, a CVD technique, and then the inorganic film is patterned by applying a photolithography technique or an etching technique. By doing so, the insulation film 71 can be formed of the inorganic material.

When the insulation film 71 will be made of an organic material such as an acrylic resin, it can be formed by applying, for example, a spin coat technique or a photolithography technique and patterning the organic film.

Then, a light-shielding film 73 is formed at the region overlapping in a plan view with the insulation film 71.

When the light-shielding film 73 will be made of an organic material such as an acrylic resin or polyimide, it can be formed by applying, for example, a spin coat technique or a photolithography technique and patterning the organic film.

Then, the pixel electrode 29 is activated by, for example, O₂ plasma treatment, and then liquid repellency is imparted to the surface of the light-shielding film 73 by, for example, CF₄ plasma treatment.

Then, as shown in FIG. 20A, a liquid 75a containing an organic material forming a hole-injecting layer 75 is disposed inside the pixel 5 region surrounded by the insulation film 71 by discharging a droplet 75b of the liquid 75a from a droplet-discharging head 121 into the pixel 5 region. The technology for discharging a liquid such as liquid 75a as droplets from the droplet-discharging head 121 is called ink-jet technology. The method for disposing a liquid such as the liquid 75a to a predetermined position by applying the ink-jet technology is called an ink-jet method. This ink-jet method is one of coating methods.

After the disposing of the liquid 75a, the liquid 75a disposed in the pixel 5 region is dried by reduced-pressure drying and is then burned to form the hole-injecting layer 75 shown in FIG. 10B. The liquid 75a containing the organic material forming the hole-injecting layer 75 can be prepared by dissolving a mixture of PEDOT and PSS in a solvent. Examples of the solvent can include diethylene glycol, isopropyl alcohol, and n-butanol. The reduced-pressure drying is a method performing drying under a reduced pressure and is also called vacuum drying. The conditions for burning the liquid 75a are an environmental temperature of about 200° C. and a holding time of about 10 minutes.

Then, as shown in FIG. 20B, a liquid 77a containing an organic material forming a hole-transporting layer 77 is disposed inside the region surrounded by the light-shielding film 73 by discharging a droplet 77b of the liquid 77a from a droplet-discharging head 121 into the region. On this occasion, the hole-injecting layer 75 is covered with the liquid 77a. The liquid 77a can be a solvent containing TFB. Examples of the solvent can include cyclohexylbenzene.

Then, the liquid 77a is dried by reduced-pressure drying and is then burned in an inert gas to form the hole-transporting layer 77 shown in FIG. 20C. The conditions for burning the liquid 77a are an environmental temperature of about 130° C. and a holding time of about one hour.

Then, as shown in FIG. 20C, a liquid 79a containing an organic material forming a light-emitting layer 79 is disposed inside the region surrounded by the light-shielding film 73 by discharging a droplet 79b of the liquid 79a from a droplet-discharging head 121 into the region. On this occasion, the hole-transporting layer 77 is covered with the liquid 79a. The liquid 79a can be a solvent containing the above-mentioned organic material corresponding to the pixel 5r, 5g, or 5b. Examples of the solvent can include cyclohexylbenzene.

Then, the liquid 79a is dried by reduced-pressure drying and is then burned in an inert gas to form the light-emitting layer 79 shown in FIG. 5. The conditions for burning the liquid 79a are an environmental temperature of about 130° C. and a holding time of about one hour.

Then, a film of, for example, ITO is formed by applying a sputtering technique, and the film is patterned by applying a photolithography technique or an etching technique to form the common electrode 33 shown in FIG. 5. Thus, the element substrate 11 can be produced.

In the process of assembling the display apparatus 1, as shown in FIG. 2, the element substrate 11 and the sealing substrate 13 are bonded to each other with the adhesive 16 and the sealing material 17.

In this occasion, as shown in FIG. 5, the element substrate 11 and the sealing substrate 13 are bonded to each other such that the first surface 42a of the first substrate 41 and the opposing surface 13b of the sealing substrate 13 face to each other. By doing so, the display apparatus 1 can be produced.

In this Embodiment, the selecting transistor 21 and the complementary TFT element each correspond to a semiconductor device, the first semiconductor layer 51 corresponds to a semiconductor layer, the first electrically conductive pattern 107 corresponds to an electrically conductive pattern, the N-type impurity corresponds to a second impurity, the first superimposed region 113a corresponds to a superimposed region, and the dose corresponds to an implantation concentration. The step of etching the first electrically conductive pattern 107, the second electrically conductive pattern 109, and the third electrically conductive pattern 111 corresponds to reduction of the superimposed region. The first implantation step corresponds to former implantation of an impurity into the semiconductor layer or former implantation of a second impurity. The second implantation step corresponds to later implantation of the impurity into the semiconductor layer or later implantation of the second impurity.

In the method for producing the display apparatus 1, a display apparatus 1 including an N-channel type TFT element and a P-channel type TFT element with respect to each excel 5 can be produced. The selecting transistor 21 as the N-channel type TFT element includes the LDD region 51d between the source region 51a and the channel region 51b and the LDD region 51e between the channel region 51b and the drain region 51c. Accordingly, the display apparatus 1 can be reduced in power consumption.

In addition, according to the method for producing the display apparatus 1, a complementary TFT element, which is a combination of the N-channel type TFT element and the P-channel type TFT element, can be formed. Therefore, when the selecting transistor 21 and the driving transistor 23 are formed, the complementary TFT element can be also formed. By doing so, a display apparatus 1 having an element substrate 11 including a scanning line driving circuit 34 and a data line driving circuit 35 to which the complementary TFT elements are applied can be produced.

In this Embodiment, when the first superimposed region 113a is reduced, etching treatment is applied to the first electrically conductive pattern 107 in a state that the third, fourth, and fifth resist patterns 101, 103, and 105 are removed and no resist pattern is newly provided. Therefore, when the first superimposed region 113a is reduced, steps of providing a resist film and a photolithography step can be omitted. As a result, it is possible to readily increase the efficiency in the method for producing the selecting transistor 21 having the LDD structure.

Furthermore, in this Embodiment, the gate electrode portion 57 is formed by etching the first electrically conductive pattern 107, and the second implantation step is performed using the gate electrode portion 57 as a mask. Therefore, the LDD region 51d and the LDD region 51e can be formed by self-alignment.

In this Embodiment, after the formation of the first electrically conductive pattern 107, the second electrically conductive pattern 109, and the third electrically conductive pattern 111 and before the first implantation step, the third resist pattern 101, the fourth resist pattern 103, and the fifth resist pattern 105 are removed.

Implantation of an impurity may make the material constituting the third resist pattern 101, the fourth resist pattern 103, or the fifth resist pattern 105 harder than before the implantation step.

In this Embodiment, since the third resist pattern 101, the fourth resist pattern 103, and the fifth resist pattern 105 are removed before the first implantation step, the third resist pattern 101, the fourth resist pattern 103, and the fifth resist pattern 105 can be removed before the hardening thereof. Accordingly, the third resist pattern 101, the fourth resist pattern 103, and the fifth resist pattern 105 can be readily removed compared to the case that the third resist pattern 101, the fourth resist pattern 103, and the fifth resist pattern 105 are removed after the first implantation step.

Furthermore, in this Embodiment, the dose (implantation concentration) in the second implantation step is different from the dose (implantation concentration) in the first implantation step. However, the dose (implantation concentration) in the second implantation step is not limited this and can be equivalent to the dose (implantation concentration) in the first implantation step. In addition, the dose (implantation concentration) in the second implantation step can be higher than the dose (implantation concentration) in the first implantation step.

This Embodiment has been described using an example in which the third resist pattern 101, the fourth resist pattern 103, and the fifth resist pattern 105 are removed before the first implantation step, but the order of the step of removing these third to fifth resist patterns 101, 103, and 105 is not limited thereto. For example, these third to fifth resist patterns 101, 103, and 105 may be removed after the first implantation step and before the etching treatment of the first electrically conductive pattern 107, the second electrically conductive pattern 109, and the third electrically conductive pattern 111. In this case, since the third to fifth resist patterns 101, 103, and 105 are removed after the first implantation step, the first electrically conductive pattern 107, the second electrically conductive pattern 109, and the third electrically conductive pattern 111 can be readily prevented from being damaged by the impurity.

Next, a second Embodiment will be described.

As shown in FIG. 21, which is a cross-sectional view taken along the line XXI-XXI in FIG. 3, a display apparatus 1 according to the second Embodiment includes an element substrate 20. The display apparatus 1 according to the second Embodiment has the same structure as that of the display apparatus 1 according to the first Embodiment except that the element substrate 20 is used instead of the element substrate 11 in the first Embodiment.

Accordingly, in the following second Embodiment, in order to avoid repeated description, the same portions as the first Embodiment are designated by the same reference numerals as the first Embodiment, and detailed descriptions thereof are omitted. Only the different portions from the first Embodiment will be described.

In the element substrate 20, the gate electrode portion 57 (scanning line GT), the gate electrode portion 55a (island electrode 55), and the data line SI each include a plurality of electrically conductive layers. In this Embodiment, the gate electrode portion 57 (scanning line GT), the gate electrode portion 55a (island electrode 55), and the data line SI each include a first electrically conductive layer 131 and a second electrically conductive layer 133. The gate electrode portion 57 (scanning line GT), the gate electrode portion 55a (island electrode 55), and the data line SI each have a structure in which the first electrically conductive layer 131 and the second electrically conductive layer 133 overlap with each other.

The thickness of the first electrically conductive layer 131 is smaller than that of the second electrically conductive layer 133. In this Embodiment, the thickness of the first electrically conductive layer 131 is about 50 nm, and the thickness of the second electrically conductive layer 133 is about 400 nm.

The first electrically conductive layer 131 is disposed on the display surface 3 side of the gate-insulating film 43. The second electrically conductive layer 133 is disposed on the display surface 3 side of the first electrically conductive layer 131.

As shown in FIG. 22, which is an enlarged view of the selecting transistor 21 in FIG. 21, the first semiconductor layer 51 includes an LDD region 51d and an LDD region 51e.

In the gate electrode portion 57, the first electrically conductive layer 131 is disposed so as to overlap with the LDD region 51d, the channel region 51b, and the LDD region 51e in a plan view. Consequently, in this Embodiment, the selecting transistor 21 has a so-called GOLD (gate-drain overlapped LDD) structure.

In the gate electrode portion 57, the second electrically conductive layer 133 is disposed so as to overlap with the channel region 51b in a plan view.

Next, the process of producing the element substrate 20 will be described.

In the process of producing the element substrate 20, a first semiconductor layer 51 and a second semiconductor layer 53 are formed, as shown in FIG. 15D, on a first substrate 41 by the same step as in the first Embodiment.

Then, as shown in FIG. 23A, a gate-insulating film 43 is formed that covers the first semiconductor layer 51 and the second semiconductor layer 53 from the display surface 3 side on the display surface 3 side of the first substrate 41. The gate-insulating film 43 can be formed by applying, for example, a CVD technique.

Then, a first electrically conductive film 131a is formed on the display surface 3 side of the gate-insulating film 43. In this Embodiment, the first electrically conductive film 131a is made of titanium. The first electrically conductive film 131a can be formed by, for example, applying a sputtering technique.

Then, a second electrically conductive film 133a is formed on the display surface 3 side of the first electrically conductive film 131a. In this Embodiment, the second electrically conductive film 133a is made of an alloy containing aluminum and neodymium. The second electrically conductive film 133a can be formed by, for example, applying a sputtering technique.

Then, as shown in FIG. 23B, resist patterns including a third resist pattern 101, a fourth resist pattern 103, and a fifth resist pattern 105 are formed on the display surface 3 side of the second electrically conductive film 133a. The third resist pattern 101 is formed so as to overlap in a plan view with the first semiconductor layer 51. The fourth resist pattern 103 is formed so as to overlap in a plan view with the second semiconductor layer 53. The fifth resist pattern 105 is formed so as to overlap in a plan view with the data line SI (FIG. 8).

Then, the first electrically conductive film 131a and the second electrically conductive film 133a are etched using the third to fifth resist patterns 101, 103, and 105 as resist masks. By doing so, as shown in FIG. 23C, a first electrically conductive pattern 131b and a second electrically conductive pattern 133b can be formed at the regions where the third, fourth, or fifth resist pattern 101, 103, or 105 overlaps therewith in a plan view. In the etching treatment on this occasion, for example, dry etching treatment using a chlorine-containing gas as an etchant can be employed.

Then, as shown in FIG. 24A, the third to fifth resistant patterns 101, 103, and 105 are removed.

Here, the region where the first semiconductor layer 51 and the second electrically conductive pattern 133b overlap with each other in a plan view is called a first superimposed region 135a, and the region where the second semiconductor layer 53 and the second electrically conductive pattern 133b overlap with each other in a plan view is called a second superimposed region 137a. The second superimposed region 137a overlaps in a plan view with part of the source region 53a and part of the drain region 53c.

After the removal of the third to fifth resist patterns 101, 103, and 105, the first electrically conductive pattern 131b and the second electrically conductive pattern 133b are etched. The etching treatment on this occasion is isotropic etching. In this etching treatment, the etching rate to the first electrically conductive pattern 131b is slower than that to the second electrically conductive pattern 133b.

The etching treatment on this occasion is wet etching. As an etchant in the wet etching, for example, TMAH can be employed.

In addition, the etching treatment on this occasion can be the dry etching treatment described above. However, the wet etching treatment can exhibit an effect of washing particles and is therefore preferred. Since dry etching treatment of an alloy containing aluminum and neodymium tends to generate particles, in this Embodiment, wet etching treatment is particularly effective.

By etching the first electrically conductive pattern 131b and the second electrically conductive pattern 133b, as shown in FIG. 24B, the first electrically conductive layer 131 and the second electrically conductive layer 133 can be formed. By doing so, the gate electrode portion 57 (scanning line GT), the gate electrode portion 55a (island electrode 55), and the data line SI can be formed.

By this etching treatment, the first superimposed region 135a is reduced to a first superimposed region 135b, and the second superimposed region 137a is reduced to a second superimposed region 137b. The first superimposed region 135b is narrower than a superimposed region 135c which is a region where the first semiconductor layer 51 and the first electrically conductive layer 131 overlap with each other in a plan view. The second superimposed region 137b is narrower than a superimposed region 137c which is a region where the second semiconductor layer 53 and the first electrically conductive layer 131 overlap with each other in a plan view. That is, in this etching treatment, the first electrically conductive pattern 131b and the second electrically conductive pattern 133b are subjected to the etching treatment such that the resulting first electrically conductive layer 131 is broader than the second electrically conductive layer 133.

Then, as shown in FIG. 24C, an N-type impurity is implanted into the first semiconductor layer 51 using the gate electrode portion 57 as a mask. As the N-type impurity, an element such as phosphorus or arsenic can be used. The implantation can be performed under conditions, for example, a dose (implantation concentration) of about 2×10¹⁵/cm² and an acceleration energy of about 50 keV.

By doing so, a source region 51a and a drain region 51c can be formed in the first semiconductor layer 51 at a region outside the first electrically conductive layer 131 in a plan view.

In the step of implanting the N-type impurity, the impurity is inhibited by the first electrically conductive layer 131 and the second electrically conductive layer 133 from reaching the first semiconductor layer 51 at the regions where the first superimposed region 135b and the superimposed region 135c overlap in a plan view with the first semiconductor layer 51.

On the other hand, the N-type impurity is implanted through the first electrically conductive layer 131 into the first semiconductor layer 51 at the region where is, in a plan view, the outside of the first superimposed region 135b, but the inside of the superimposed region 135c. Consequently, in the first semiconductor layer 51, the concentration of the N-type impurity in the region between the source region 51a and the first superimposed region 135b is lower than that in the source region 51a. Similarly, in the first semiconductor layer 51, the concentration of the N-type impurity in the region between the drain region 51c and the first superimposed region 135b is lower than that in the drain region 51c.

With this, as shown in FIG. 22, the LDD region 51d and the LDD region 51e can be formed.

In the second Embodiment, the first electrically conductive pattern 131b and the second electrically conductive pattern 133b each correspond to an electrically conductive pattern, the second electrically conductive layer 133 corresponds to another conductive layer, and the first superimposed region 135a corresponds to a superimposed region.

In the method for producing the display apparatus 1 in this Embodiment, a display apparatus 1 including an N-channel type TFT element and a P-channel type TFT element with respect to each excel 5 can be produced. The selecting transistor 21 as the N-channel type TFT element includes the LDD region 51d between the source region 51a and the channel region 51b and the LDD region 51e between the channel region 51b and the drain region 51c. In addition, in the gate electrode portion 57, the first electrically conductive layer 131 is provided so as to overlap in a plan view with the LDD region 51d, the channel region 51b, and the LDD region 51e. Therefore, a GOLD structure is applied to the selecting transistor 21, and thereby deterioration in the ON current value due to hot carriers can be suppressed. As a result, it is possible to readily improve the reliability of the display apparatus 1.

In addition, according to the method for producing the display apparatus 1, a complementary TFT element, which is a combination of an N-channel type TFT element and a P-channel type TFT element, can be also formed. Therefore, when the selecting transistor 21 and the driving transistor 23 are formed, the complementary TFT element can be also formed. With this, a display apparatus 1 having the element substrate 20 including a scanning line driving circuit 34 and a data line driving circuit 35 to which the complementary TFT elements are applied can be produced.

In this Embodiment, when the first superimposed region 135a is reduced, etching treatment is applied to the first electrically conductive pattern 131b and the second electrically conductive pattern 133b in a state that the third to fifth resist patterns 101, 103, and 105 are removed and a resist pattern or the like is not newly provided. Therefore, when the first superimposed region 135a is reduced, steps of providing a resist film and photolithography can be omitted. As a result, it is possible to readily increase the efficiency in the method for producing the selecting transistor 21 having the GOLD structure.

Furthermore, in this Embodiment, the gate electrode portion 57 is formed by etching the first electrically conductive pattern 131b and the second electrically conductive pattern 133b, and a implantation step is performed using the gate electrode portion 57 as a mask. Therefore, the LDD region 51d and the LDD region 51e can be formed by self-alignment.

The display apparatus 1 has been described using an example of a top-emission organic EL device in which light from the organic layer 31 is emitted from the display surface 3 through the sealing substrate 13, but the organic EL device is not limited thereto. The organic EL device may be a bottom-emission type in which light from the organic layer 31 is emitted from the bottom face 15 through the element substrate 11 or the element substrate 20.

In the bottom-emission type, since light from the organic layer 31 is emitted from the bottom face 15, the display surface 3 is provided at the bottom face 15 side. That is, in the bottom-emission type, the bottom face 15 and the display surface 3 of the display apparatus 1 are replaced by each other: the bottom face 15 side corresponds to the upper side, and the display surface 3 side corresponds to the lower side.

In addition, in this Embodiment, the display apparatus 1 has been described using the organic EL device as an example, but the display apparatus 1 is not limited thereto. As the display apparatus 1, a liquid crystal device having liquid crystal that can modify light can be also applied.

The above-described display apparatus 1 can be applied to, for example, a display 510 of electronic equipment 500 shown in FIG. 25. The electronic equipment 500 is a mobile phone. This electronic equipment 500 has operation buttons 511. The display 510 can display contents inputted with the operation buttons 511 or various information such as incoming information. In this electronic equipment 500, since the display apparatus 1 is applied to the display 510, a reduction in power consumption and an improvement in reliability of the display apparatus 1 can be achieved.

The electronic equipment 500 is not limited to mobile phones, and examples thereof include various electronic equipment such as mobile computers, digital still cameras, digital video cameras, in-car devices such as displays for car navigation systems and audio equipment.

What is claimed is:

1. A method for producing a semiconductor device comprising:
forming an electrically conductive pattern so as to overlap in a plan view with part of a semiconductor layer provided on a substrate, on opposite side of the substrate side of the semiconductor layer;
implanting an impurity into the semiconductor layer using the electrically conductive pattern as a mask;
reducing a superimposed region that is a region where the electrically conductive pattern and the semiconductor layer overlap with each other in a plan view by removing part of the electrically conductive pattern after the implantation of the impurity; and
implanting the impurity into the semiconductor layer using the electrically conductive pattern as a mask after the reduction of the superimposed region.

2. The method for producing a semiconductor device according to claim 1, wherein the implantation concentrations of the impurity in the former implantation and the later implantation are different from each other.

3. The method for producing a semiconductor device according to claim 2, wherein the implantation concentration of the impurity in the later implantation is lower than that in the former implantation.

4. The method for producing a semiconductor device according to claim 2, wherein the implantation concentration of the impurity in the later implantation is higher than that in the former implantation.

5. The method for producing a semiconductor device according to claim 1, wherein
the formation of the electrically conductive pattern comprises:
forming an electrically conductive film in a region covering the semiconductor layer in a plan view;
forming a resist pattern so as to overlap in a plan view with part of the semiconductor layer on the opposite side of the semiconductor layer side of the electrically conductive film; and
etching the electrically conductive film using the resist pattern as a resist mask, and
the reduction of the superimposed region is performed by etching the electrically conductive pattern in a state that the resist pattern is removed to remove part of the electrically conductive pattern.

6. The method for producing a semiconductor device according to claim 5, further comprising:
removing the resist pattern between the formation of the electrically conductive pattern and the former implantation of the impurity.

7. The method for producing a semiconductor device according to claim 5, further comprising:
removing the resist pattern between the former implantation of the impurity and the reduction of the superimposed region.

8. The method for producing a semiconductor device according to claim 5, wherein the etching treatment in the reduction of the superimposed region is isotropic etching.

9. The method for producing a semiconductor device according to claim 5, wherein the etching treatment in the reduction of the superimposed region is wet etching.

10. A method for producing a semiconductor device comprising:
forming an electrically conductive pattern having a laminate structure including a plurality of electrically conductive layers such that the electrically conductive pattern overlaps in a plan view with part of a semiconductor layer provided on a substrate, on opposite side of the substrate side of the semiconductor layer;
reducing a superimposed region that is a region where the electrically conductive layers and the semiconductor layer overlap with each other in a plan view by removing part of the electrically conductive pattern such that, among the plurality of electrically conductive layers, a first electrically conductive layer that is nearest the semiconductor layer remains so as to be broader than other electrically conductive layer(s) in a plan view, after the formation of the electrically conductive pattern; and
implanting an impurity into the semiconductor layer using the electrically conductive pattern as a mask, after the reduction of the superimposed region.

11. The method for producing a semiconductor device according to claim 10, wherein
the formation of the electrically conductive pattern comprises:
forming a laminate of a plurality of electrically conductive layers in a region covering the semiconductor layer in a plan view;
forming a resist pattern so as to overlap in a plan view with part of the semiconductor layer, on the opposite side of the semiconductor layer side of the plurality of electrically conductive layers; and
etching the plurality of electrically conductive layers using the resist pattern as a resist mask, and
the reduction of the superimposed region is performed by etching the plurality of electrically conductive layers in a state that the resist pattern is removed to remove part of the electrically conductive pattern.

12. The method for producing a semiconductor device according to claim 11, wherein
the etching treatment in the reduction of the superimposed region is isotropic etching, and
the etching rate for the first electrically conductive layer is slower than that for the other electrically conductive layer(s).

13. The method for producing a semiconductor device according to claim 11, wherein the etching treatment in the reduction of the superimposed region is wet etching.

14. A method for producing a semiconductor device comprising:
forming a first resist pattern and a second resist pattern including a first region having a thickness smaller than that of the first resist pattern and a second region having a thickness larger than that of the first resist pattern at different regions on a semiconductor layer disposed on a substrate, on opposite side of the substrate side of the semiconductor layer;
implanting a first impurity into the semiconductor layer using the first resist pattern and the second resist pattern as masks;
forming a first semiconductor layer so as to overlap in a plan view with the first resist pattern and a second semiconductor layer so as to overlap in a plan view with the second resist pattern by etching the semiconductor layer using the first resist pattern and the second resist pattern as resist masks;
forming an electrically conductive film that covers the first semiconductor layer and the second semiconductor layer in a plan view, on the opposite side of the substrate side of the first semiconductor layer and the second semiconductor layer;
forming a third resist pattern so as to overlap in a plan view with part of the first semiconductor layer and a fourth resist pattern so as to overlap in a plan view with part of the second semiconductor layer on the opposite side of the substrate side of the electrically conductive film;
forming a first electrically conductive pattern so as to overlap in a plan view with the third resist pattern and a second electrically conductive pattern so as to overlap in a plan view with the fourth resist pattern by etching the electrically conductive film using the third resist pattern and the fourth resist pattern as resist masks;
implanting a second impurity into the first semiconductor layer and the second semiconductor layer using the first electrically conductive pattern and the second electrically conductive pattern as masks;
reducing a first superimposed region that is a region where the first electrically conductive pattern and the first semiconductor layer overlap with each other in a plan view and a second superimposed region that is a region where the second electrically conductive pattern and the second semiconductor layer overlap with each other in a plan view by removing part of the first electrically conductive pattern and part of the second electrically conductive pattern, after the implantation of the second impurity; and
implanting the second impurity into the first semiconductor layer and the second semiconductor layer using the first electrically conductive pattern and the second electrically conductive pattern as masks, after the reduction of the first and the second superimposed regions, wherein
the reduction of the superimposed regions is performed by etching the first electrically conductive pattern and the second electrically conductive pattern in a state that the third resist pattern and the fourth resist pattern are removed to remove part of the first electrically conductive pattern and part of the second electrically conductive pattern.

15. A method for producing a semiconductor device comprising:
forming a first resist pattern and a second resist pattern including a first region having a thickness smaller than that of the first resist pattern and a second region having a thickness larger than that of the first resist pattern at different regions on a semiconductor layer disposed on a substrate, on opposite side of the substrate side of the semiconductor layer;
forming a first semiconductor layer so as to overlap in a plan view with the first resist pattern and a second semiconductor layer so as to overlap in a plan view with the second resist pattern by etching the semiconductor layer using the first resist pattern and the second resist pattern as resist masks;
implanting a first impurity into the second semiconductor layer through the first region using the first resist pattern and the second resist pattern as masks;
forming an electrically conductive film that covers the first semiconductor layer and the second semiconductor layer in a plan view on the opposite side of the substrate side of the first semiconductor layer and the second semiconductor layer;
forming a third resist pattern so as to overlap in a plan view with part of the first semiconductor layer and a fourth resist pattern so as to overlap in a plan view with part of the second semiconductor layer on the opposite side of the substrate side of the electrically conductive film;
forming a first electrically conductive pattern so as to overlap in a plan view with the third resist pattern and a second electrically conductive pattern so as to overlap in a plan view with the fourth resist pattern by etching the electrically conductive film using the third resist pattern and the fourth resist pattern as resist masks;
implanting a second impurity into the first semiconductor layer and the second semiconductor layer using the first electrically conductive pattern and the second electrically conductive pattern as masks;
reducing a first superimposed region that is a region where the first electrically conductive pattern and the first semiconductor layer overlap with each other in a plan view and a second superimposed region that is a region where the second electrically conductive pattern and the second semiconductor layer overlap with each other in a plan view by removing part of the first electrically conductive pattern and part of the second electrically conductive pattern, after the implantation of the second impurity; and
implanting the second impurity into the first semiconductor layer and the second semiconductor layer using the first electrically conductive pattern and the second electrically conductive pattern as masks, after the reduction of the first and the second superimposed regions, wherein
the reduction of the superimposed regions is performed by etching the first electrically conductive pattern and the second electrically conductive pattern in a state that the third resist pattern and the fourth resist pattern are removed to remove part of the first electrically conductive pattern and part of the second electrically conductive pattern.

16. The method for producing a semiconductor device according to claim 14, further comprising:
removing the third resist pattern and the fourth resist pattern after the formation of the electrically conductive pattern and before the former implantation of the second impurity.

17. The method for producing a semiconductor device according to claim 14, further comprising:
removing the third resist pattern and the fourth resist pattern after the former implantation of the second impurity and before the reduction of the superimposed regions.
